(19) United States
(12) Patent Application Publication
(10) Pub. No.: US 2015/0371895 A1
(43) Pub. Date: Dec. 24, 2015

(54) METHOD FOR MANUFACTURING SMEICONDUCTOR DEVICE

(71) Applicant: Masahiro Yokomichi, Tokyo (JP)

(72) Inventor: Masahiro Yokomichi, Tokyo (JP)

(21) Appl. No.: 14/766,361

(22) PCT Filed: Feb. 6, 2014
(86) PCT No.: PCT/JP2014/052724

§ 371 Date: Aug. 6, 2015

(30) Foreign Application Priority Data
Feb. 8, 2013 (JP) 2013-023194

(51) Int. Cl. H01L 21/768; H01L 49/02

(52) U.S. Cl. CPC H01L 21/76802; H01L 21/76877; H01L 28/60

(57) ABSTRACT

In one embodiment, a first insulating film is formed with a recess portion left therein in a contact hole, and the contact hole is surrounded by a first line pattern and a second line pattern, the first line pattern and the second line pattern having different heights. The recess portion is filled so as to form a first mask film, and the first insulating film except for the recess portion is etched back so as to be removed, thereby forming a second contact hole. After that, a conductive material is implanted in the second contact hole, and the top surface of the first line pattern having a low height is exposed, thereby forming a contact plug.

### TECHNICAL FIELD

The present invention relates to a method for manufacturing a semiconductor device.

### BACKGROUND

Methods for forming miniature contact plugs are being investigated as semiconductor devices become even smaller. In this context, Patent Document 1 describes a method in which a conductive material in which a large contact hole is formed in advance is divided and miniaturized, and because there is a lot of scope in the processing margin, this is a very effective method.

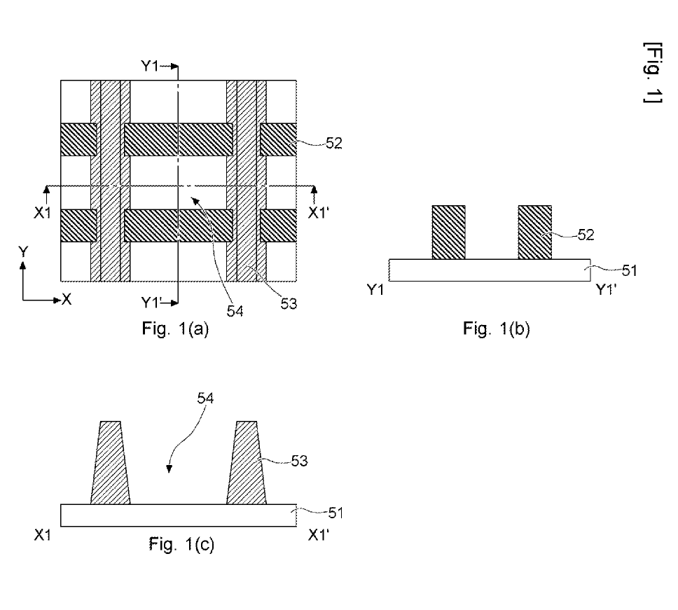

FIG. 1-6 are outline diagrams schematically showing the method for forming contact plugs described in Patent Document 1, where (a) is a plan view, (b) is a view in the cross section Y1-Y1′ in (a), (c) is a view in the cross section X1-X1′ (a), (d) is a view in the cross section Y2-Y2′ in (a), and (e) is a partial enlargement. It should be noted that these drawings were drafted by the present inventor in order to provide an understanding of the method for forming contact plugs described in Patent Document 1 and to explain problems which may arise, and the drawings do not represent the actual state of the art.

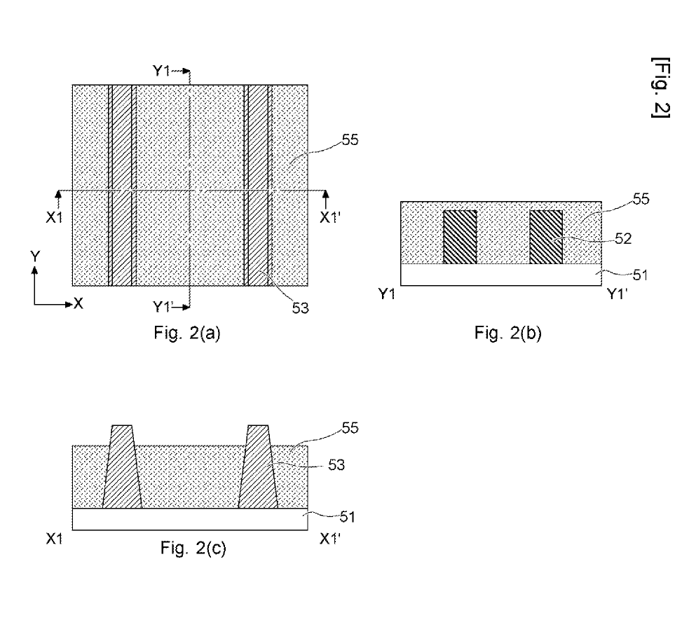

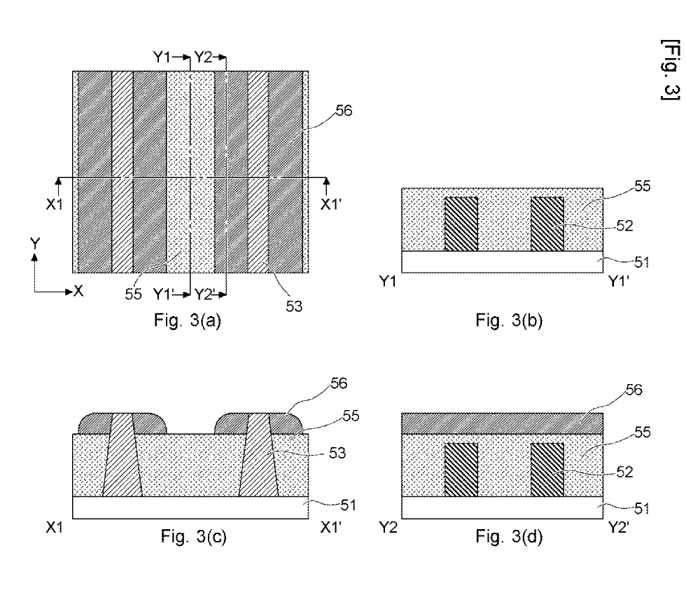

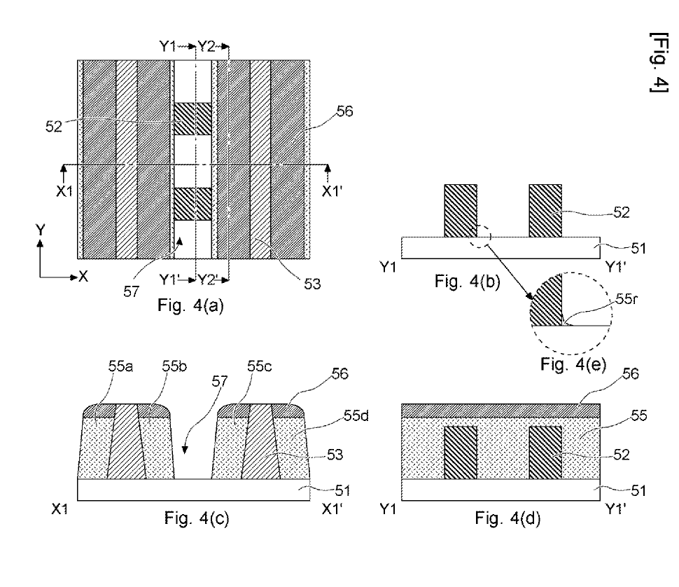

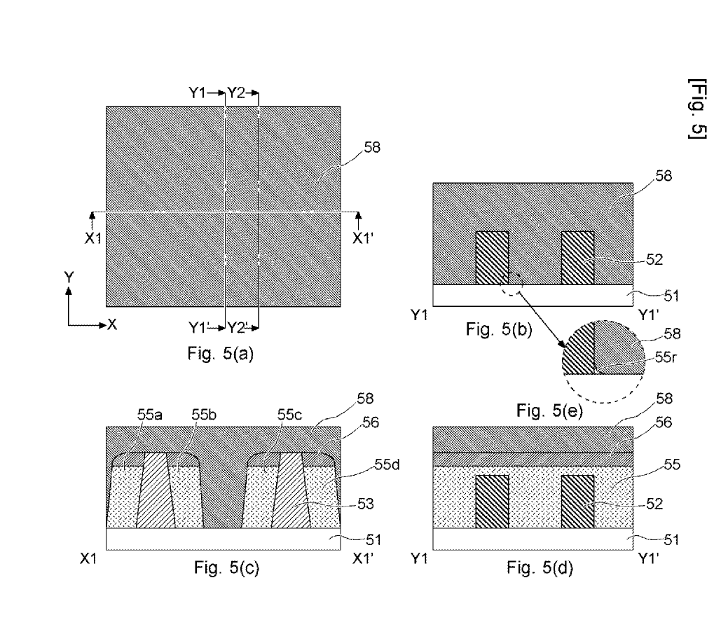

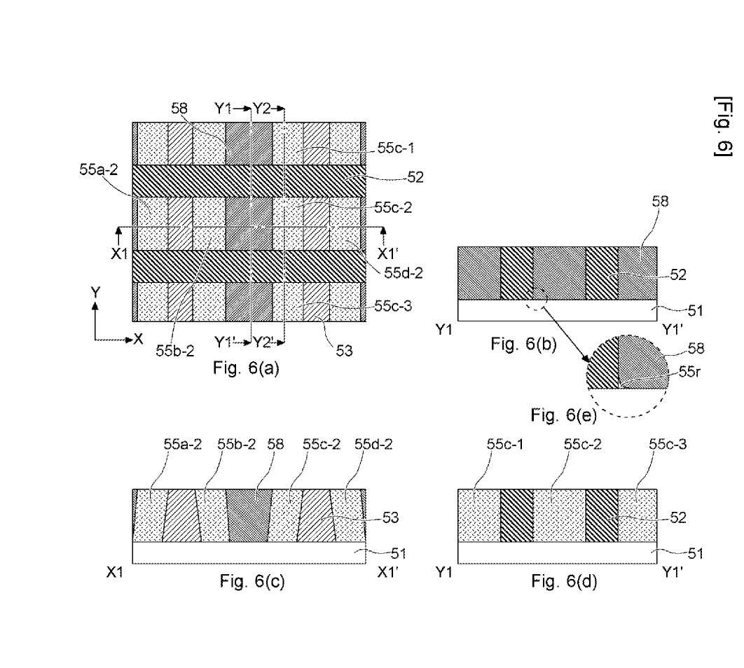

First of all, as shown in FIG. 1, first line patterns 52 extending in the X-direction and second line patterns 53 extending across the first line patterns 52 in the Y-direction and having inclined side surfaces are formed on a substrate 51, and a large contact hole 54 enclosed by the first and second line patterns is formed. Next, as shown in FIG. 2, the contact hole 54 is filled and a conductive material 55 is embedded up to a position below the upper part of the second line patterns 53. After this, as shown in FIG. 3, side walls 56 are formed on the lateral walls of the second line patterns 53 while some of the conductive material 55 is exposed. In addition, as shown in FIG. 4, the conductive material 55 is etched using the side walls 56 as a mask, thereby forming an opening 57, and the conductive material 55 is divided in the X-direction. The conductive material 55 which has been divided in the X-direction is shown as 55a-55d. At this stage, the conductive material 55 is joined in the Y-direction over the first line patterns 52. After this, as shown in FIG. 5, an isolation insulating film 58 is embedded in the opening 57, and as shown in FIG. 6, the conductive material 55 is also divided in the Y-direction by planarization using CMP or the like until the first line patterns are exposed, whereby the contact plugs are completed. The completed contact plugs that have been divided in the Y-direction are denoted as 55c-1 to 55c-3. Here, looking at the contact plugs 55b-2 and 55c-2, two plugs having a symmetrical structure are formed either side of the isolation insulating film 58 so these are referred to as “twin plugs”. These twin plugs are formed in such a way that the distance between centers on the upper surfaces is greater than the distance between centers on the bottom surfaces, and it is possible to connect to the upper-layer structure having a large gap from the lower-layer structure having a narrow gap.

In Patent Document 1, the method for forming these twin plugs is applied to capacitance contact plugs in an embedded gate-type memory cell, and this makes it possible to form contact plugs in which a narrow diffusion layer gap can be expanded to a wide gap suitable for arranging a capacitor. In this case, bit lines in the memory cell are effectively used as the first line patterns.

### Patent Document

### Patent Document 1: JP 2011-243960 A

### SUMMARY OF THE INVENTION

### Problem to be Solved by the Invention

According to the abovementioned prior art, in the step shown in FIG. 4, the separation at the bottom part of the opening 57 is occasionally inadequate due to non-uniformity within the etching plane because of the difference in level of the first line patterns 52, and a residue 55r may remain, as shown in FIG. 4(e). Because the opening is subsequently filled with the isolation insulating film 58, the residue 55r remains as it is (FIG. 6(e)) and the two plugs 55b-2 and 55c-2 which are divided in the X-direction may short-circuit, producing a reduction in yield. There is therefore room for further improvement in the prior art.

### Means for Solving the Problem

According to the present invention, the lack of separation in the twin-plug contact plugs is resolved by forming an isolation insulating film beforehand.

That is to say, a mode of embodiment of the present invention provides a method for manufacturing a semiconductor device, said method comprising the following steps:

a step in which a plurality of first line patterns extending in a first direction and arranged at predetermined intervals are formed on a substrate;
a step in which a plurality of second line patterns which are at a higher level than the first line patterns and extend over the first line patterns in a second direction orthogonal to the first direction are formed on the substrate;
a step in which a first insulating film having different etching selectivity than the surfaces of the first and second line patterns is formed to a thickness that forms a recess between the upper surfaces of the second line patterns;
a step in which a first mask film which fills the recess and has different etching selectivity than the first insulating film is formed on the first insulating film;
a step in which the first mask film is etched to expose the first insulating film, the first insulating film is preferentially further etched so that the first insulating film below the first mask film in the recess remains, and an opening is formed which exposes part of the substrate surface enclosed by the first and second line patterns along the side surfaces of the second line patterns;
a step in which a conductive material is formed by filling the opening; and
a step in which the conductive material is etched back to expose the upper surface of the first line patterns, and a plurality of contact plugs are formed which are separated in the second direction by the first line patterns and are separated in the first direction by the second line patterns and the first insulating film.

### Advantage of the Invention

According to a mode of embodiment of the present invention, an insulating film separating twin plugs is disposed in the center of a contact hole for forming the twin plugs before said twin plugs are formed, so there are no problems in terms of short-circuiting between plugs caused by insufficient removal of conductive material.

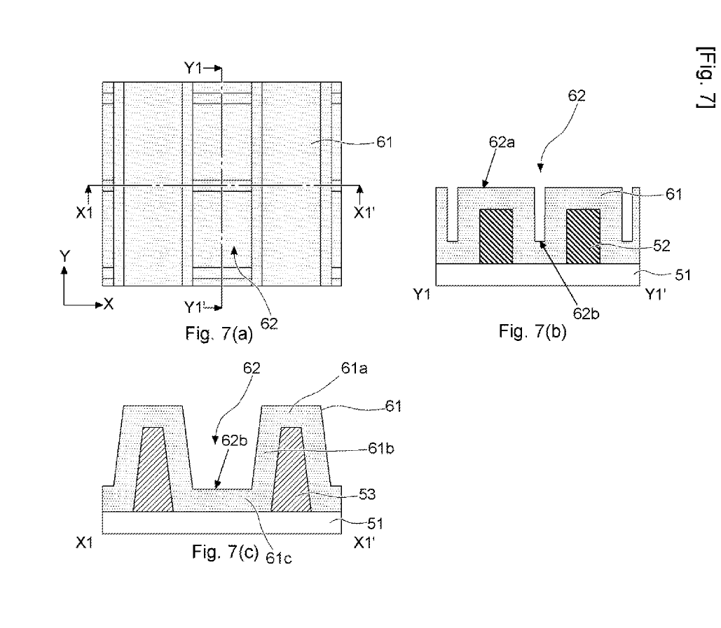

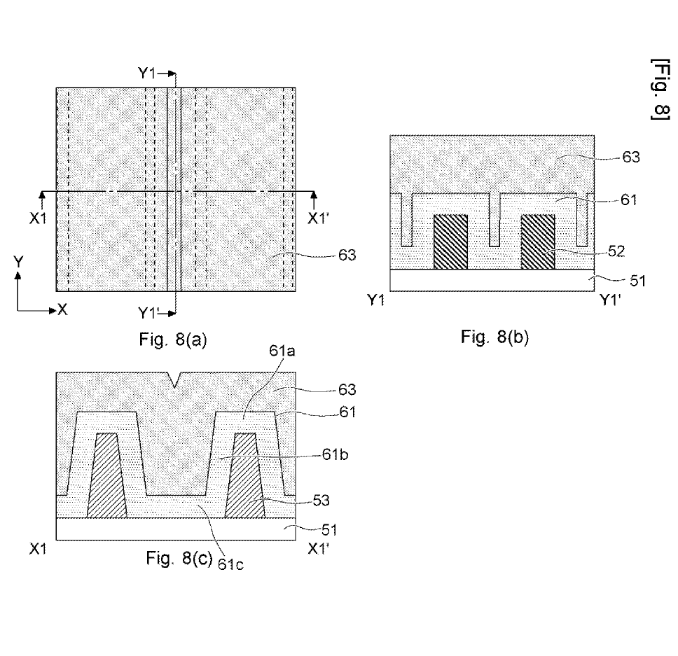

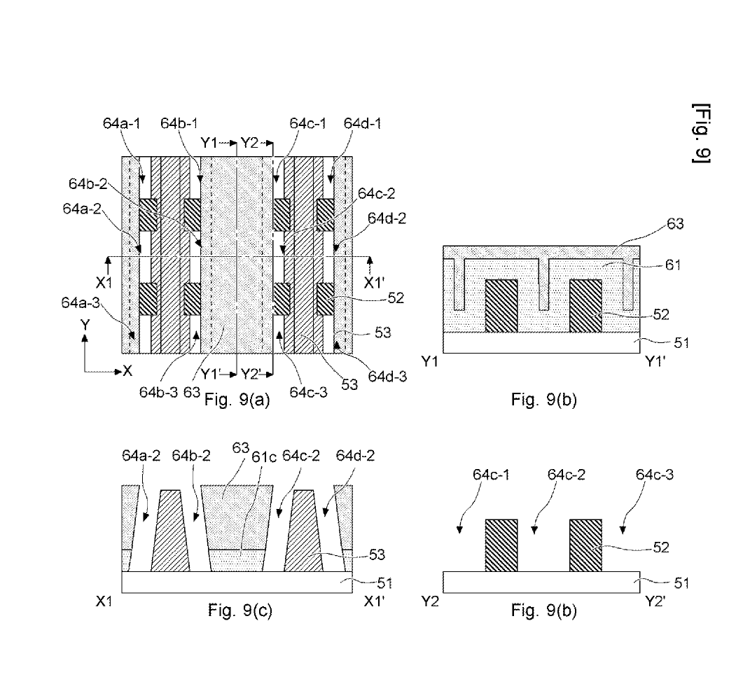

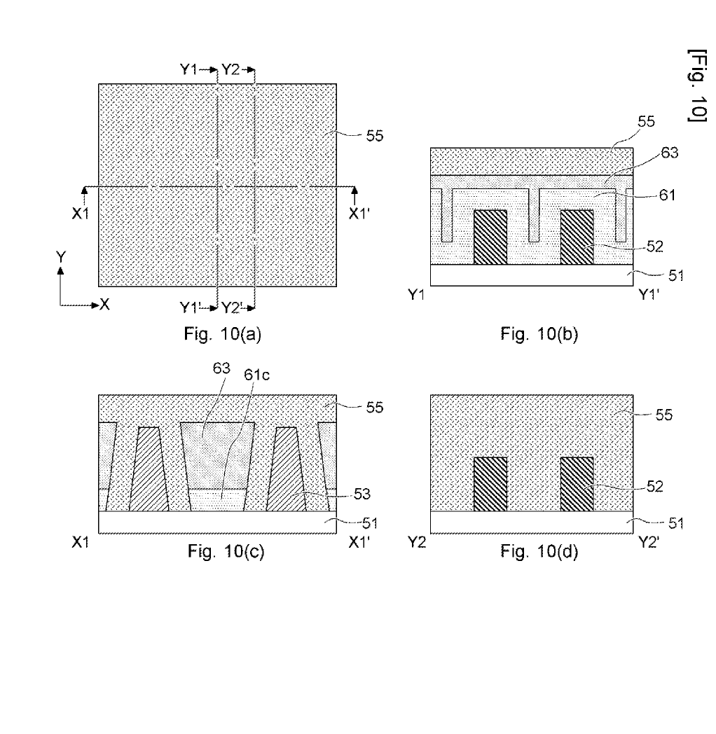

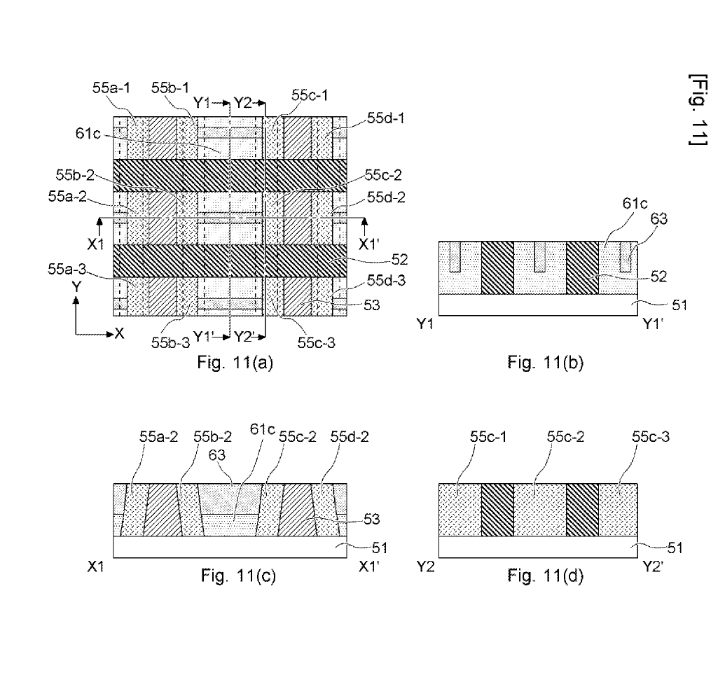

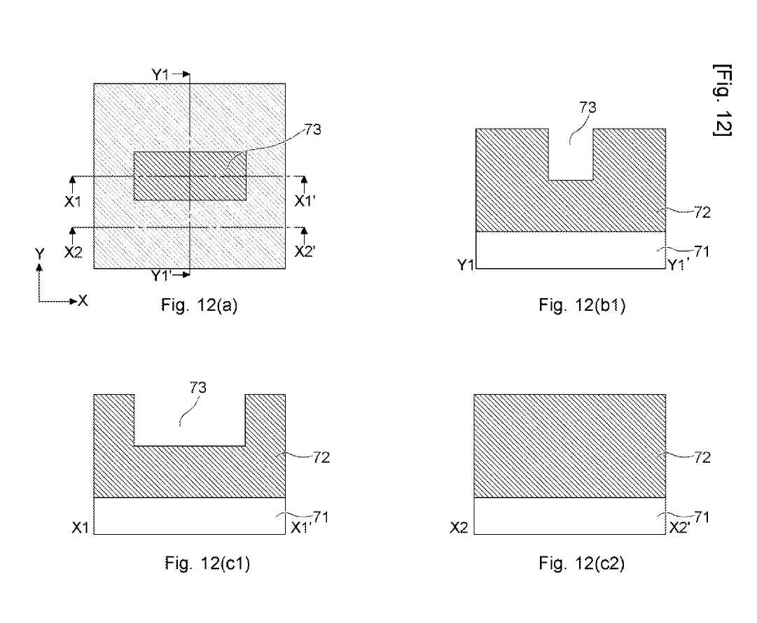

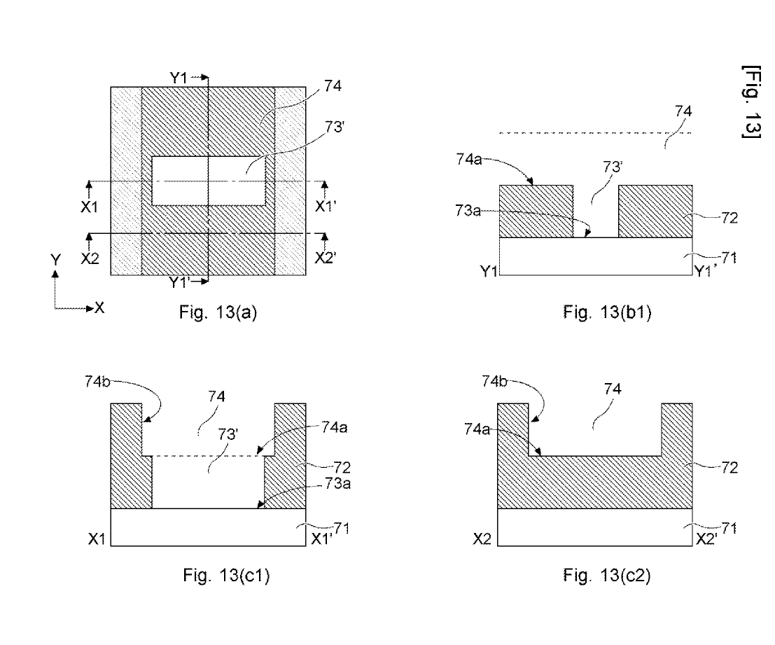

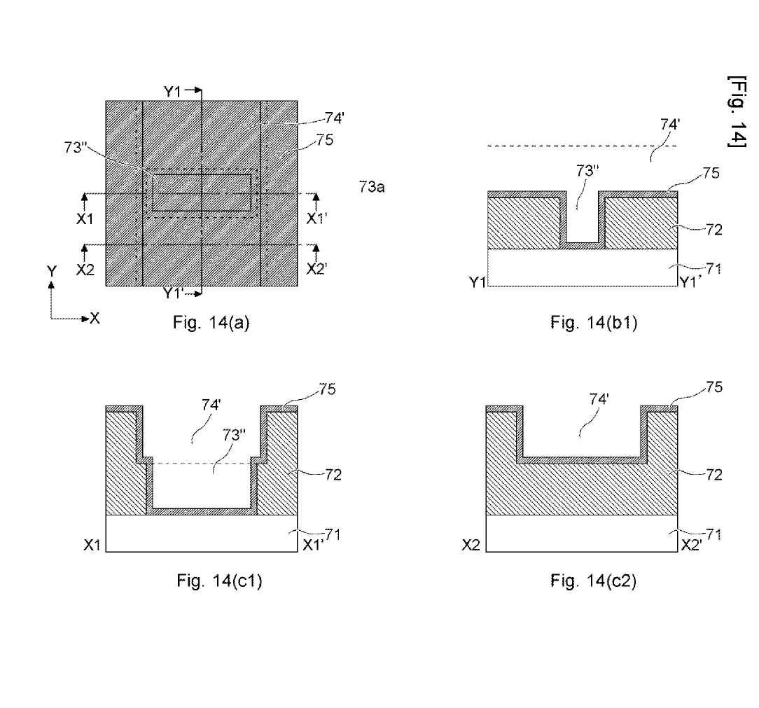

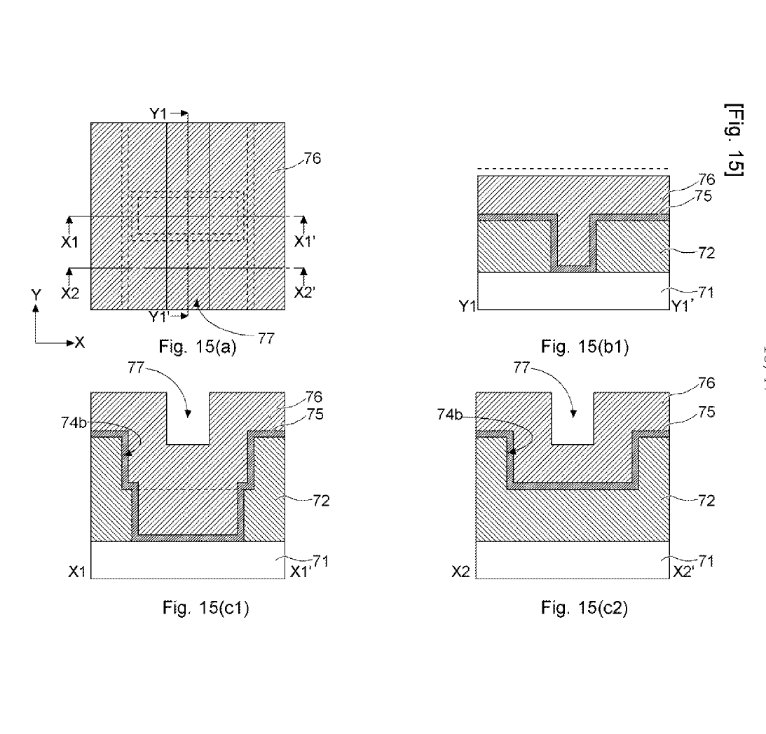

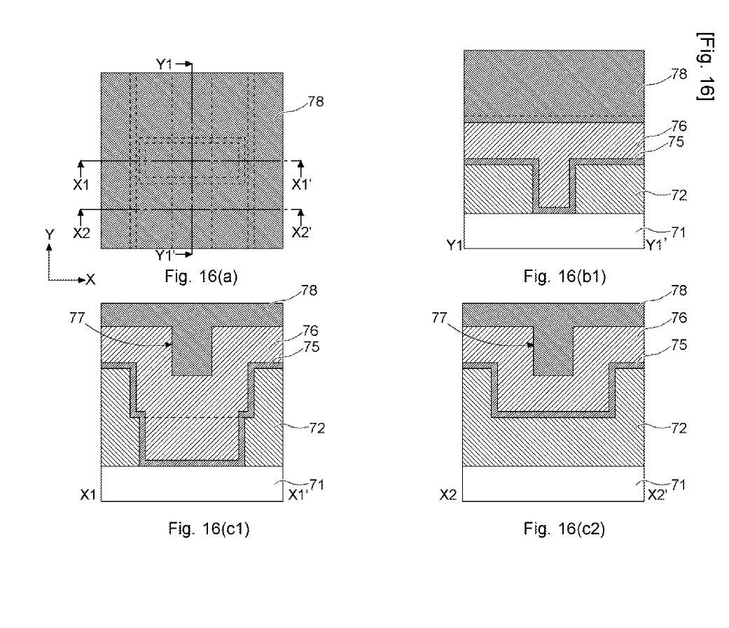

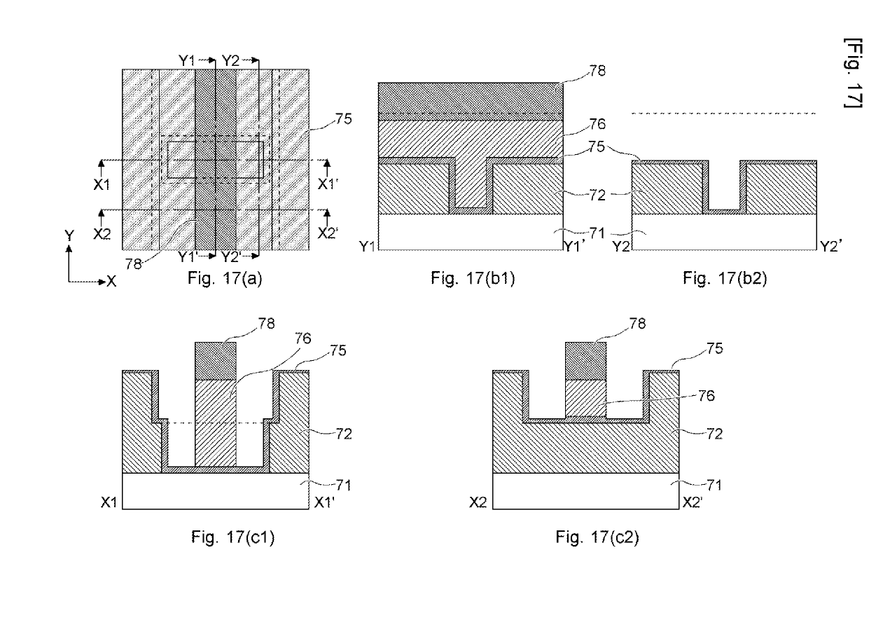

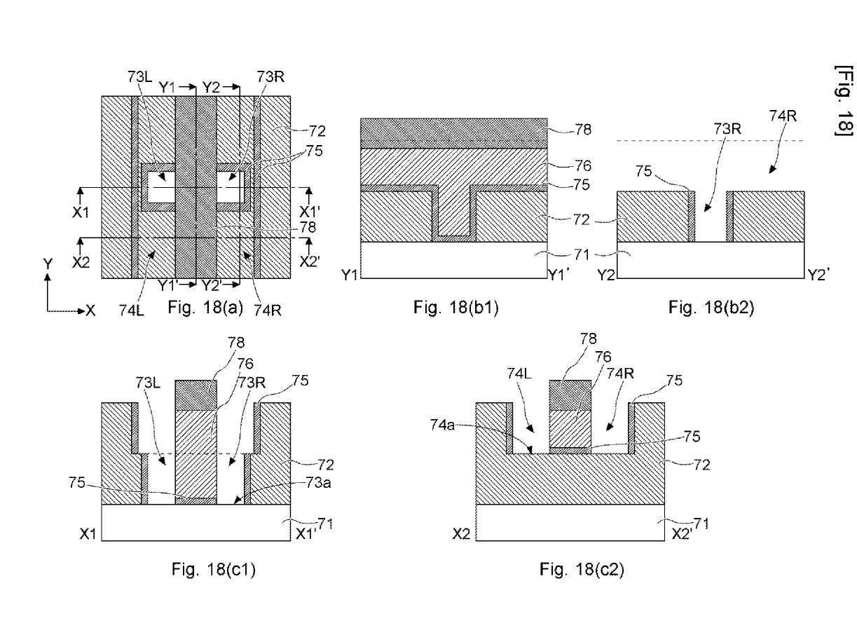

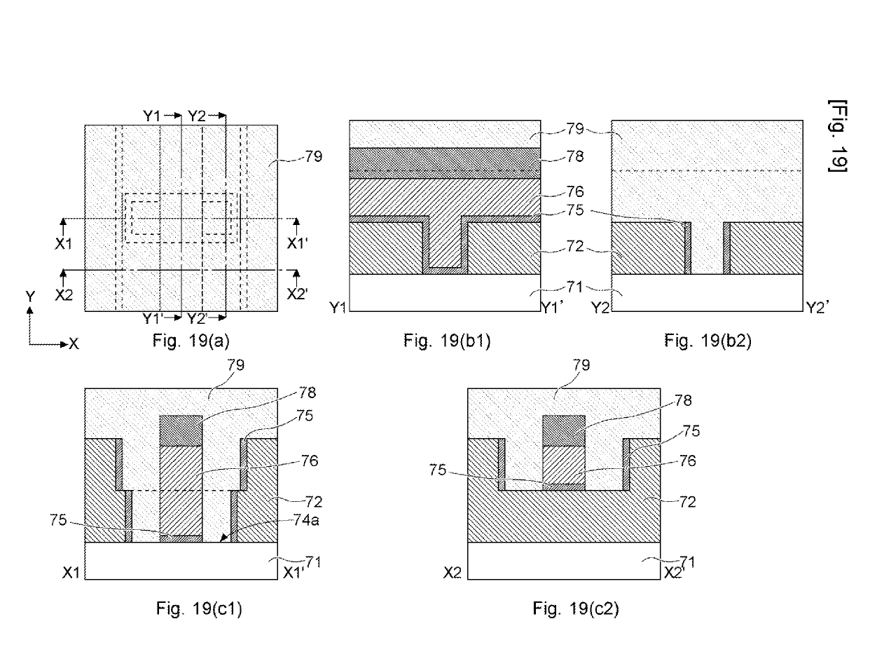

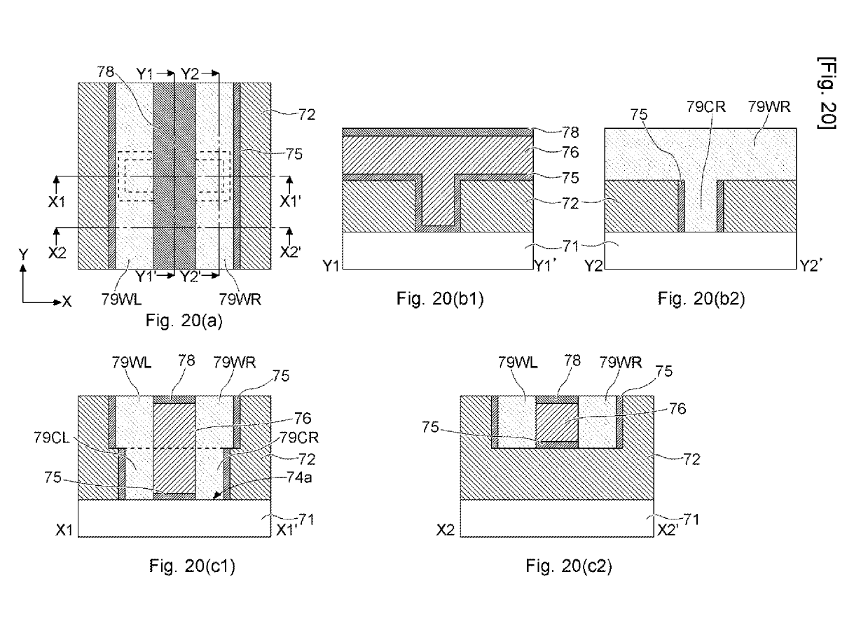

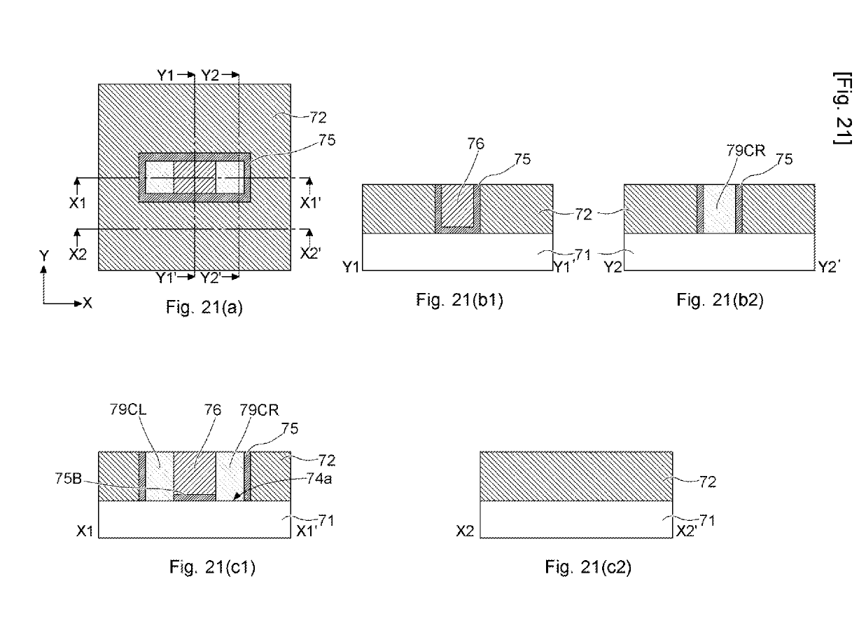

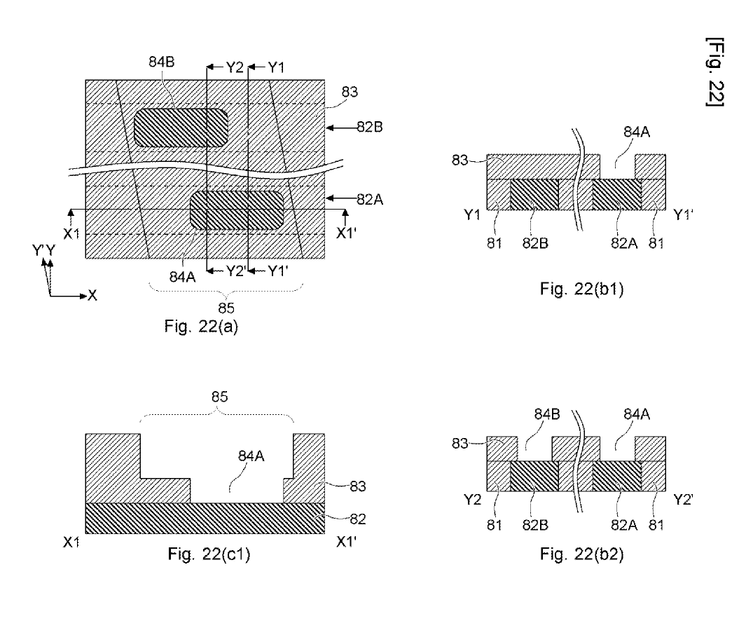

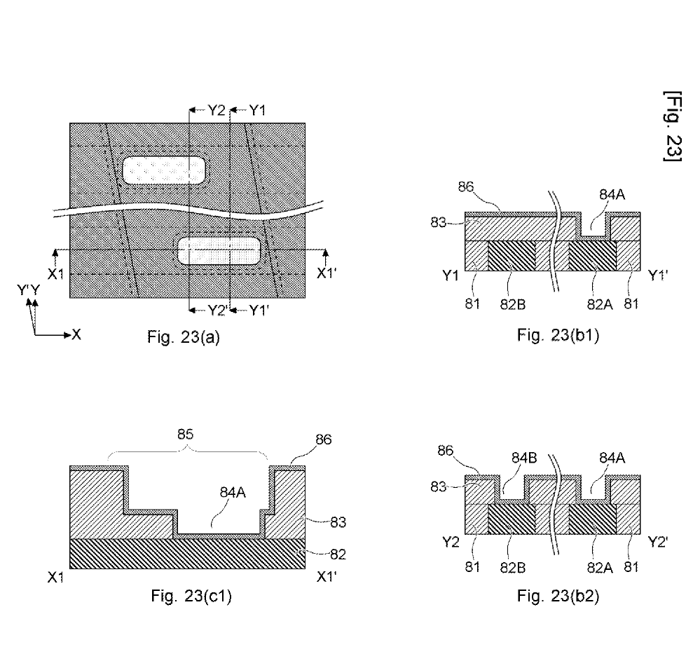

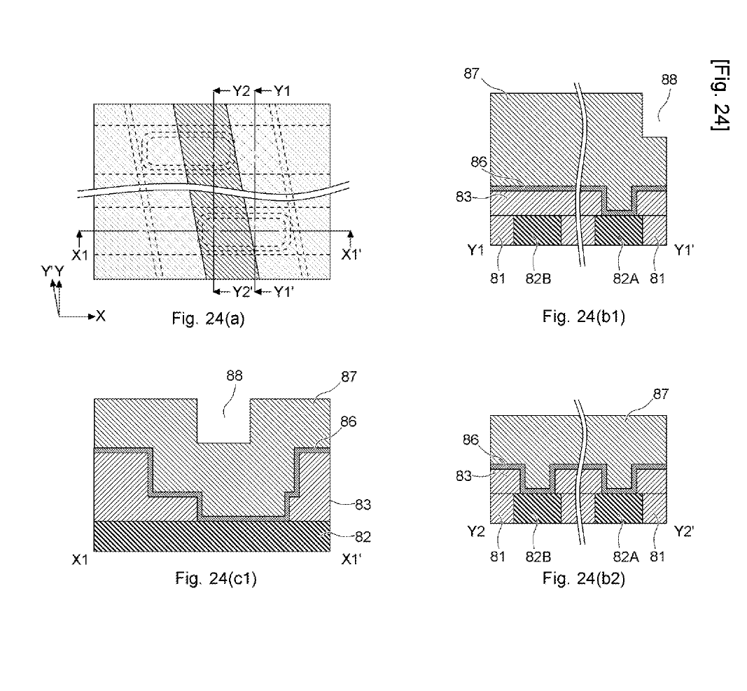

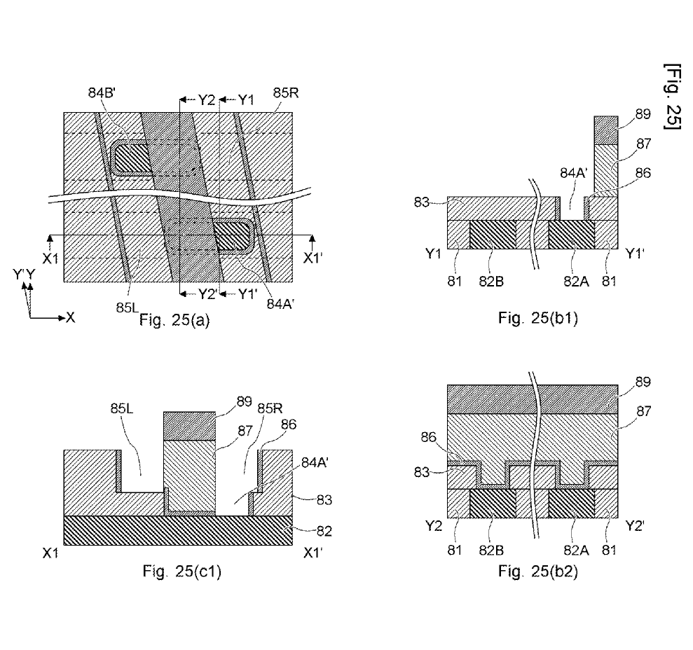

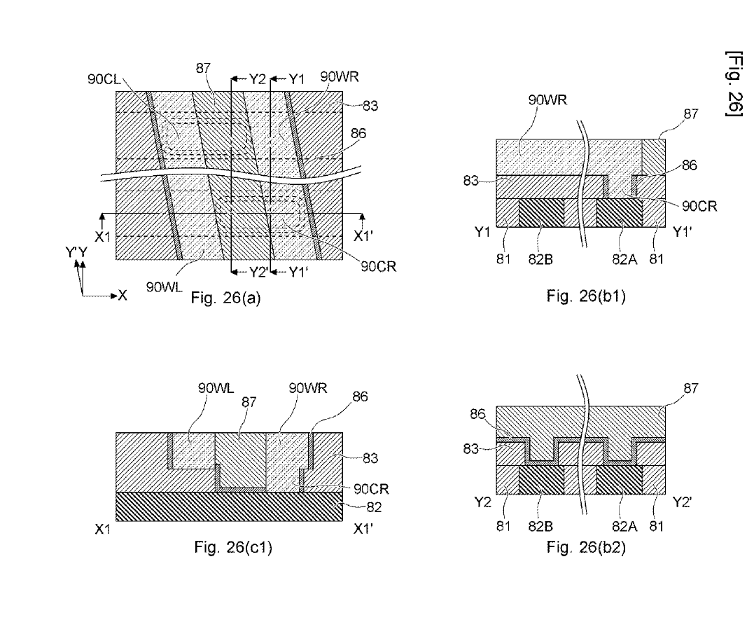

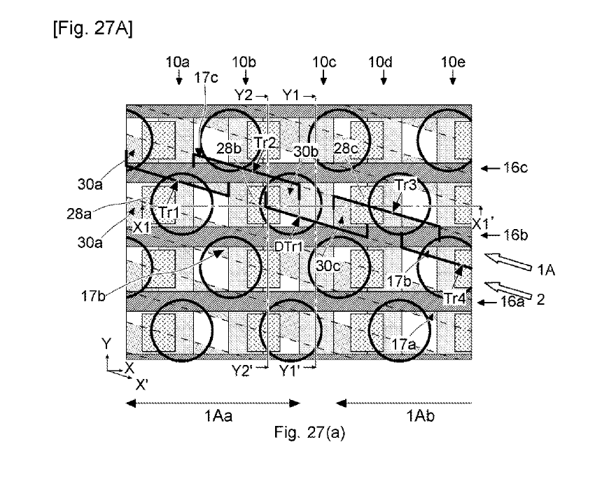

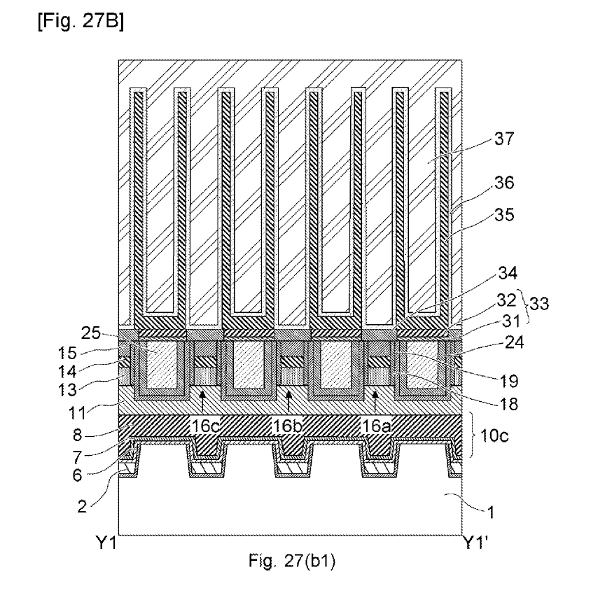

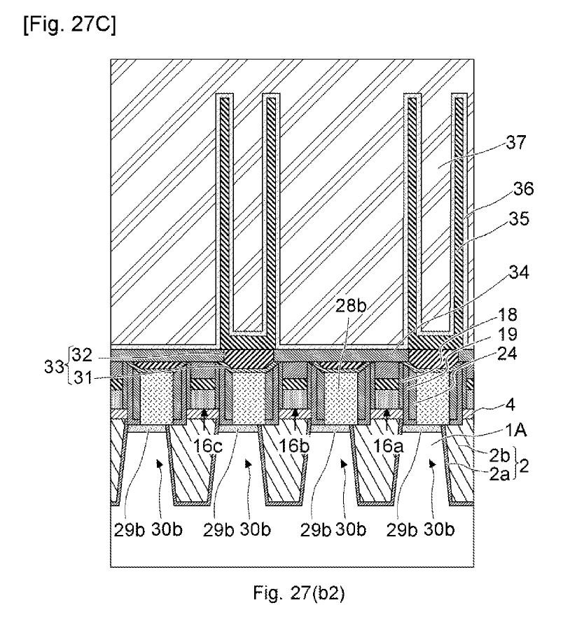

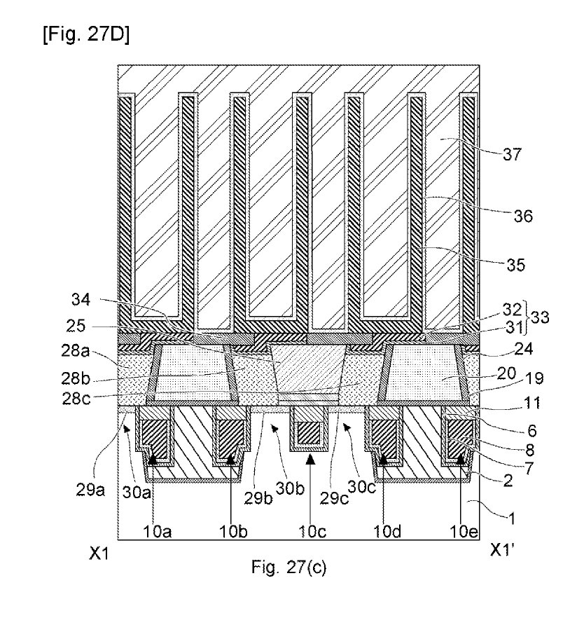

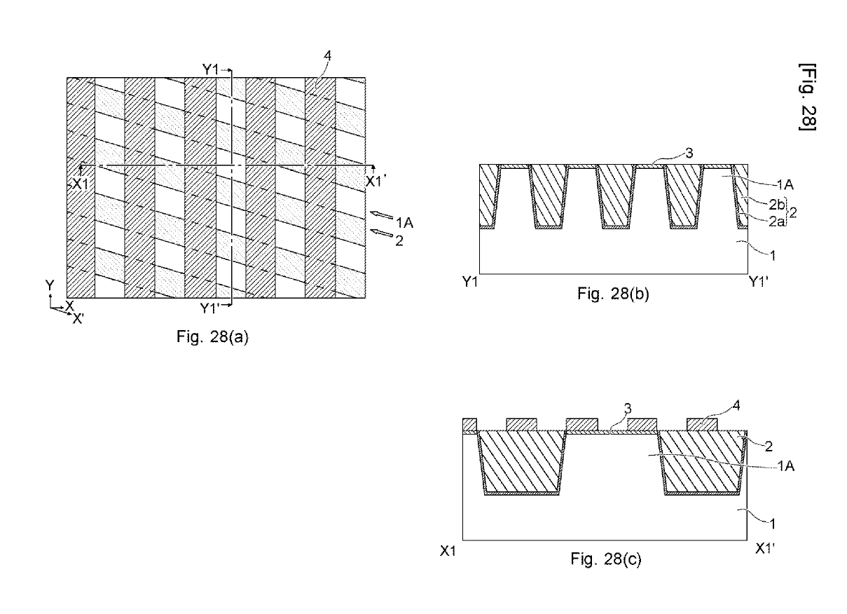

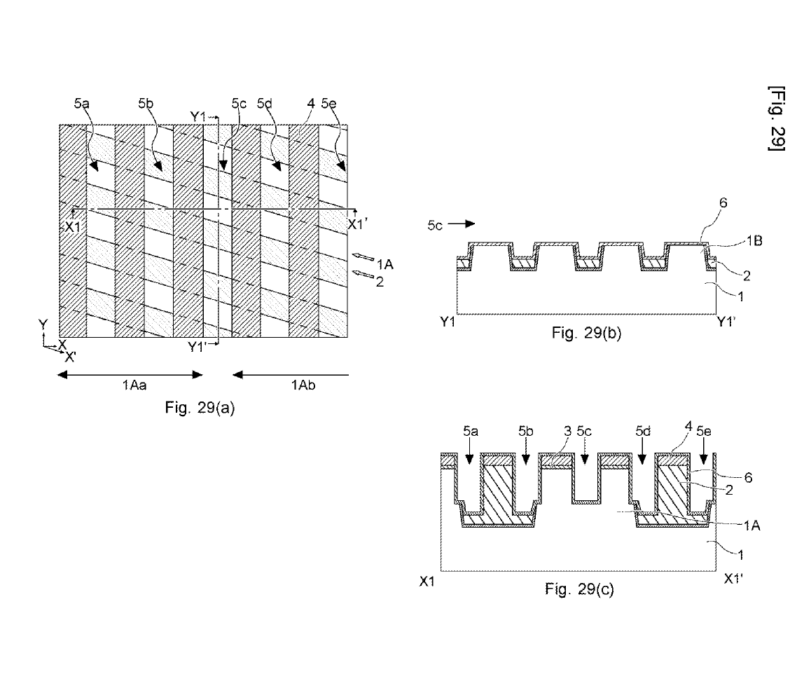

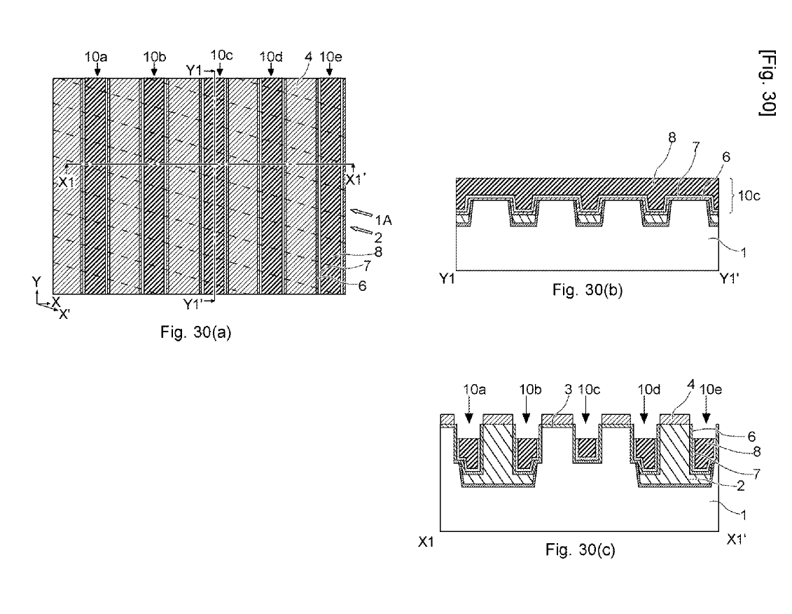

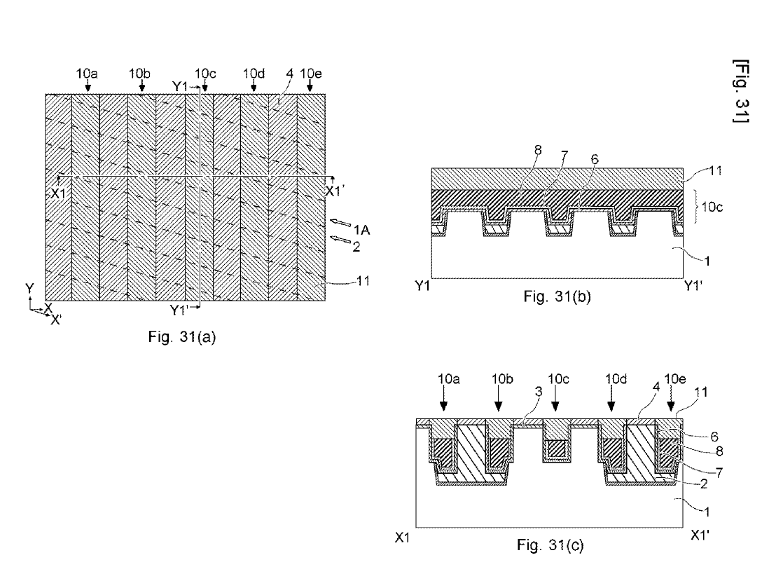

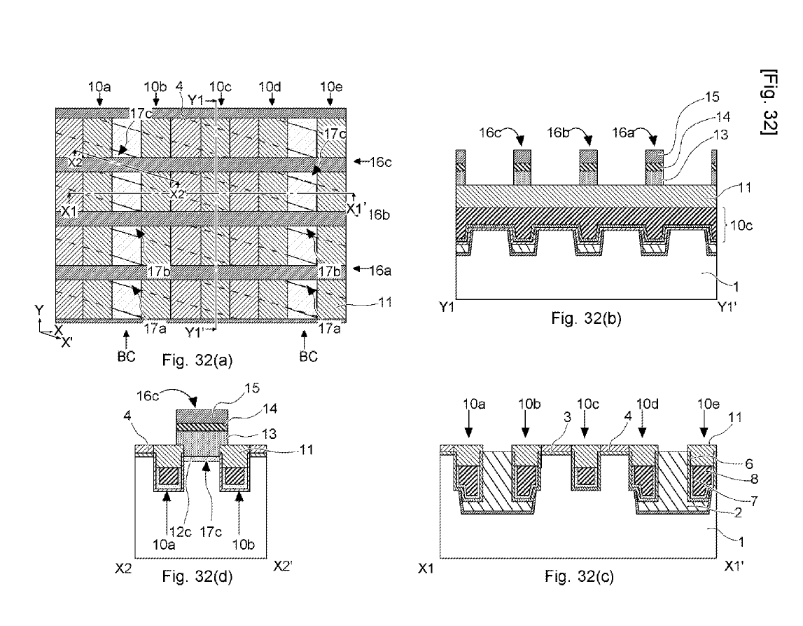

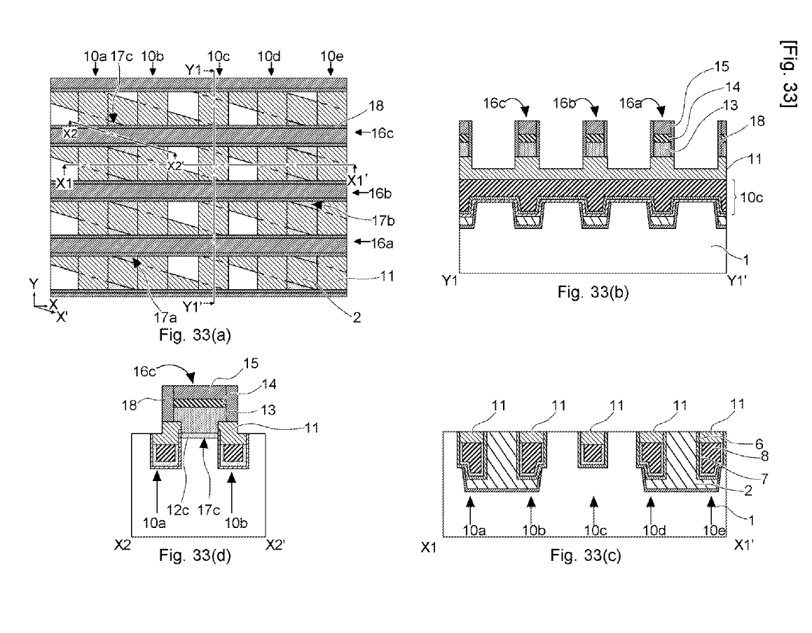

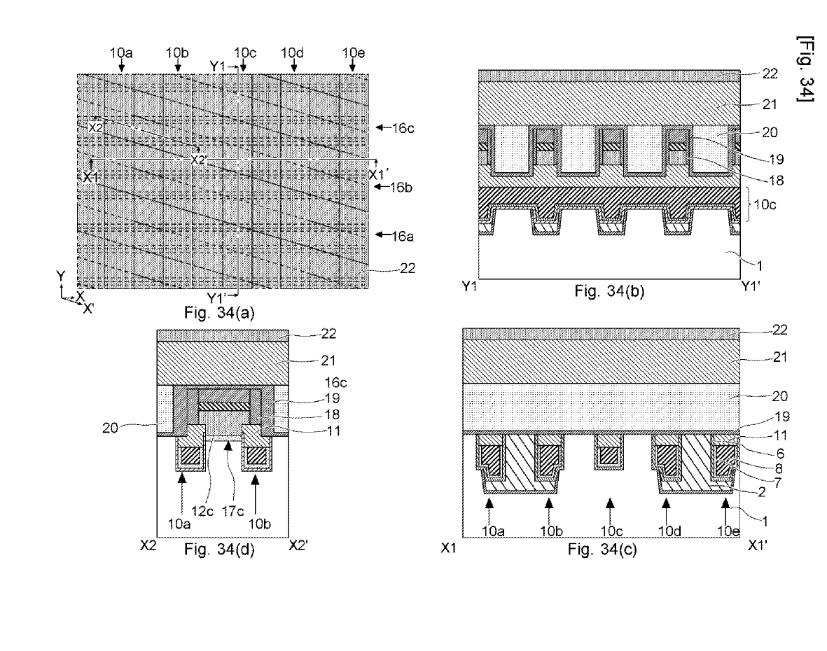

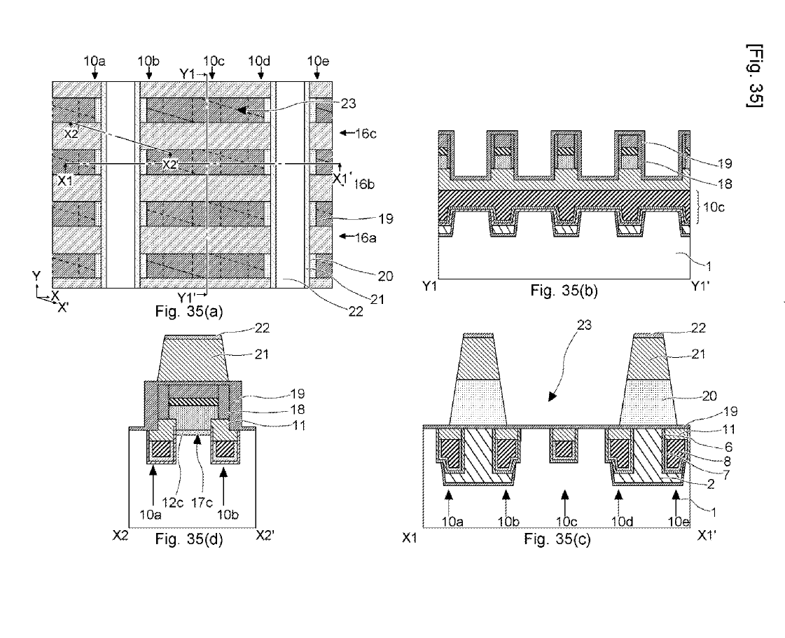

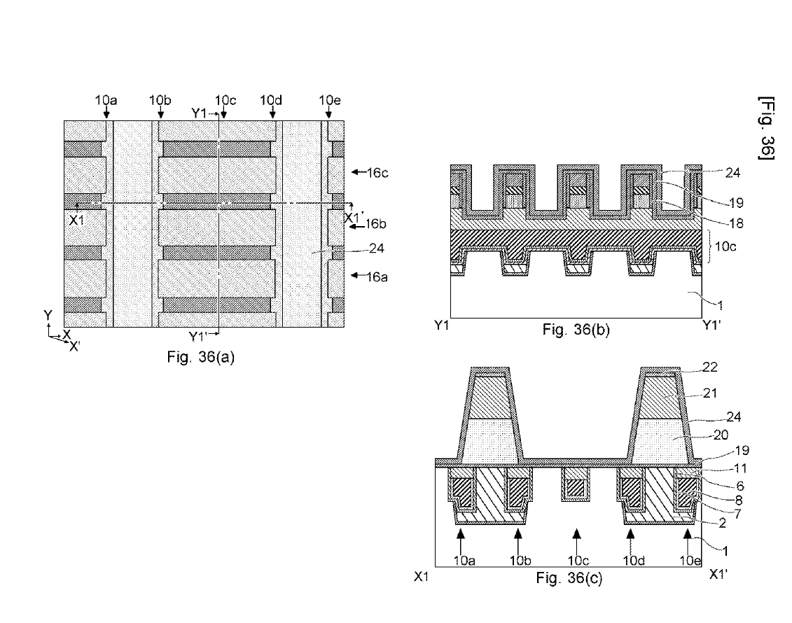

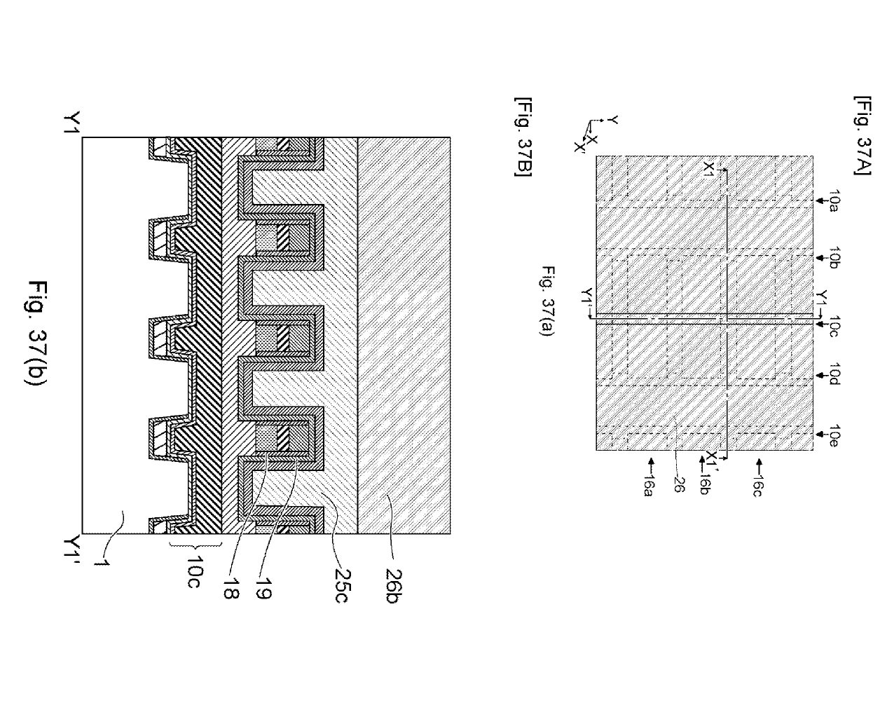

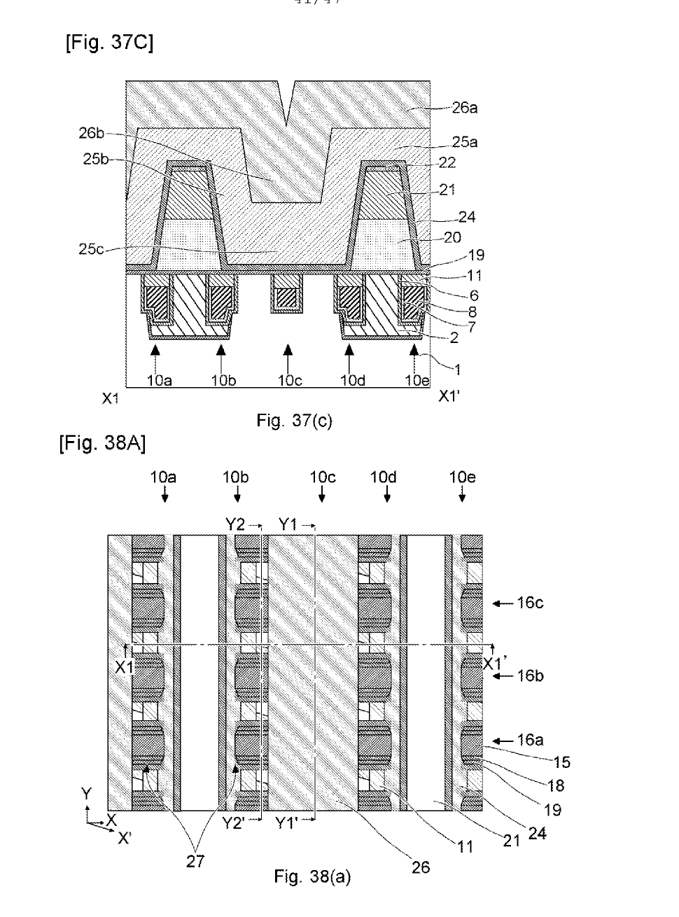

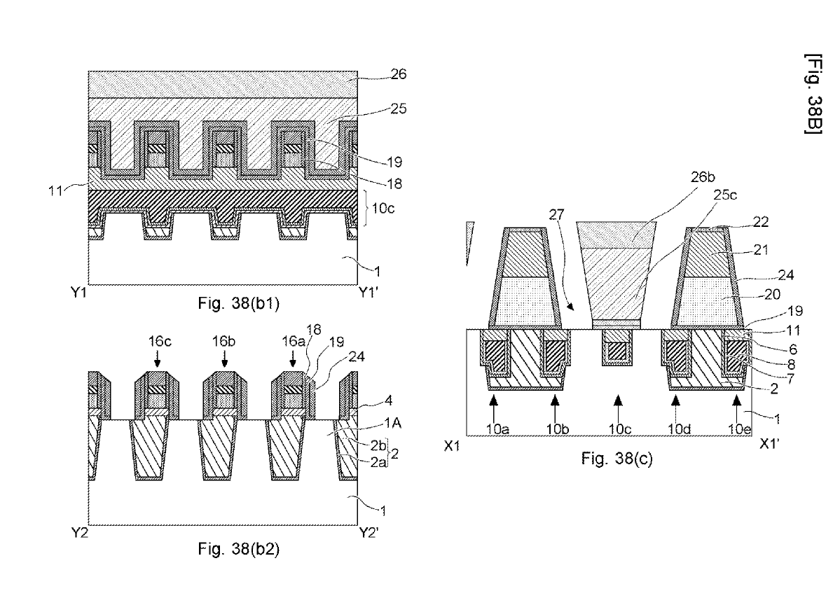

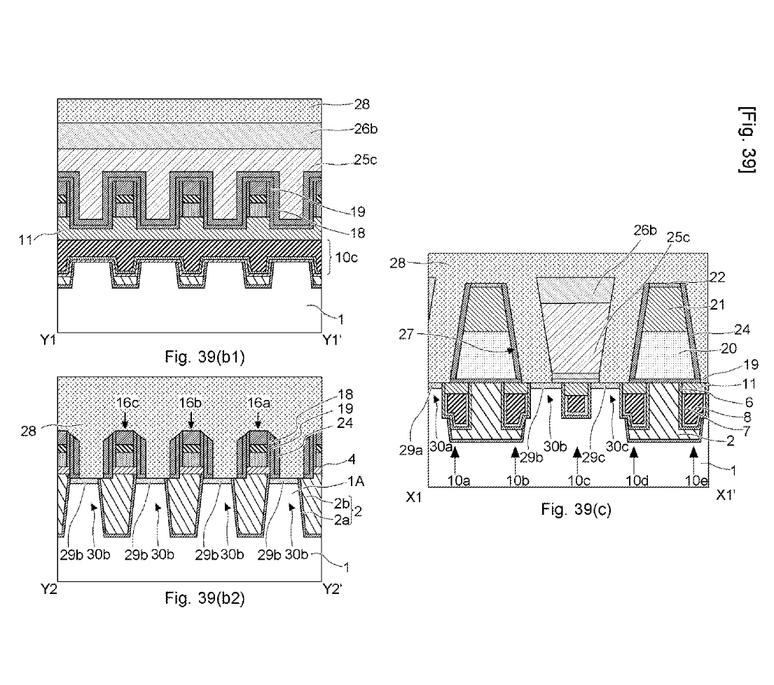

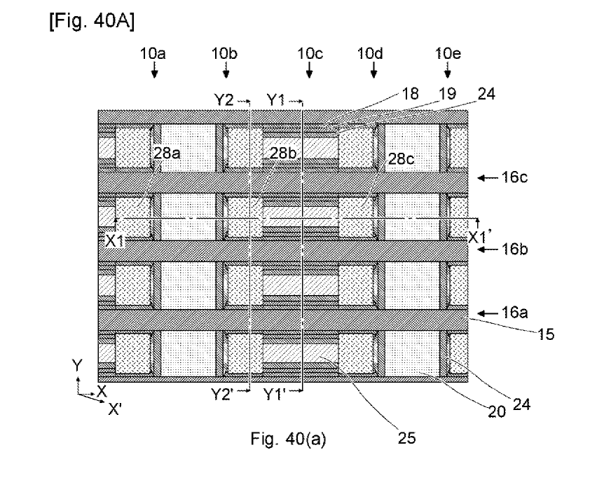

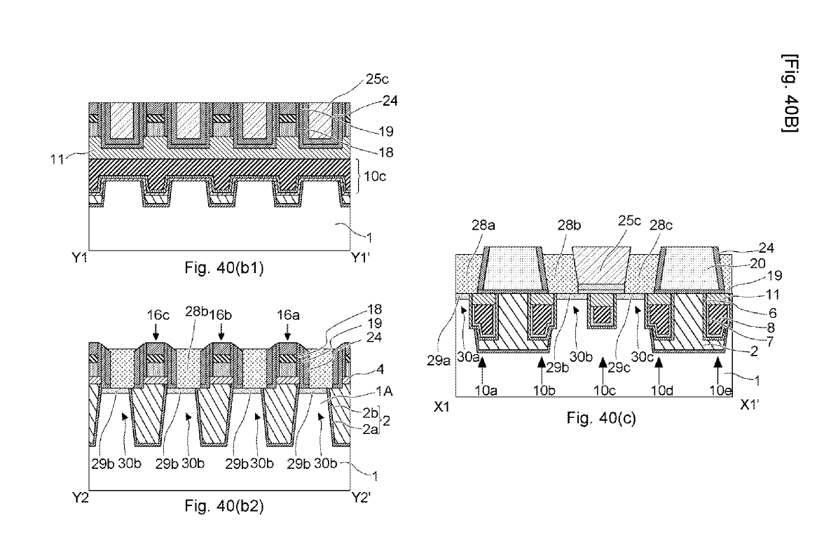

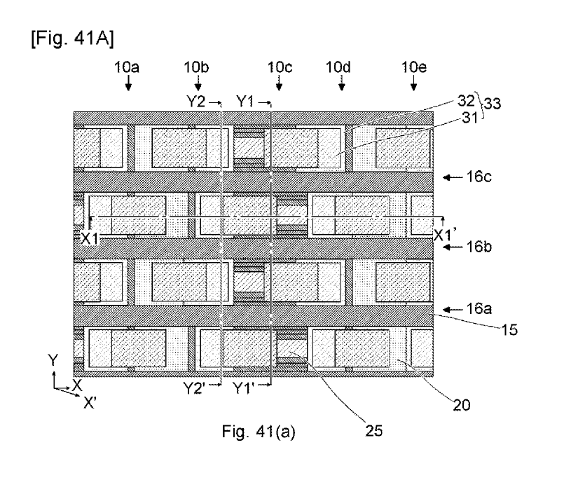

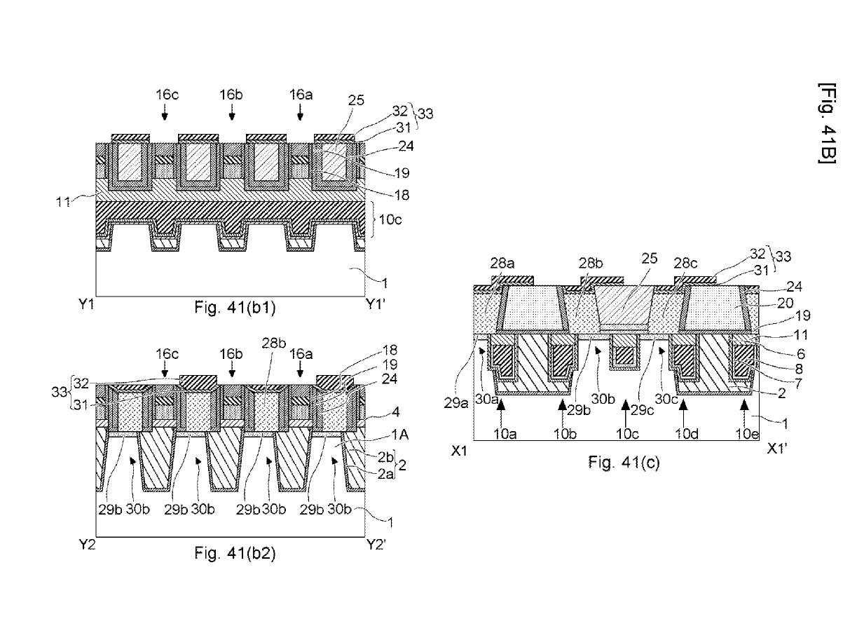

### BRIEF DESCRIPTION OF THE FIGURES

[FIG. 1] is a schematic diagram illustrating a method for forming a contact plug according to the present invention and according to a conventional example, where FIG. 1(a) is a plan view, and FIG. 1(b) and FIG. 1(c) are views in the cross sections Y1-Y1′ and X1-X1′, respectively, in FIG. 1(a);

[FIG. 2] is a schematic diagram illustrating a method for forming a contact plug according to a conventional example, where FIG. 2(a) is a plan view, and FIG. 2(b) and FIG. 2(c) are views in the cross sections Y1-Y1′ and X1-X1′, respectively, in FIG. 2(a);

[FIG. 3] is a schematic diagram illustrating a method for forming a contact plug according to a conventional example, where FIG. 3(a) is a plan view, and FIG. 3(b), FIG. 3(c) and FIG. 3(d) are views in the cross sections Y1-Y1′, X1-X1′ and Y2-Y2′, respectively, in FIG. 3(a);

[FIG. 4] is a schematic diagram illustrating a method for forming a contact plug according to a conventional example, where FIG. 4(a) is a plan view, and FIG. 4(b), FIG. 4(c) and FIG. 4(d) are views in the cross sections Y1-Y1′, X1-X1′ and Y2-Y2′, respectively, in FIG. 4(a);

[FIG. 5] is a schematic diagram illustrating a method for forming a contact plug according to a conventional example, where FIG. 5(a) is a plan view, and FIG. 5(b), FIG. 5(c) and FIG. 5(d) are views in the cross sections Y1-Y1′, X1-X1′ and Y2-Y2′, respectively, in FIG. 5(a);

[FIG. 6] is a schematic diagram illustrating a method for forming a contact plug according to a conventional example, where FIG. 6(a) is a plan view, and FIG. 6(b), FIG. 6(c) and FIG. 6(d) are views in the cross sections Y1-Y1′, X1-X1′ and Y2-Y2′, respectively, in FIG. 6(a);

[FIG. 7] is a schematic diagram illustrating a method for forming a contact plug according to an exemplary embodiment of the present invention, where FIG. 7(a) is a plan view, and FIG. 7(b) and FIG. 7(c) are views in the cross sections Y1-Y1′ and X1-X1′, respectively, in FIG. 7(a);

[FIG. 8] is a schematic diagram illustrating a method for forming a contact plug according to an exemplary embodiment of the present invention, where FIG. 8(a) is a plan view, and FIG. 8(b), FIG. 8(c) and FIG. 8(d) are views in the cross sections Y1-Y1′, X1-X1′ and Y2-Y2′, respectively, in FIG. 8(a);

[FIG. 9] is a schematic diagram illustrating a method for forming a contact plug according to an exemplary embodiment of the present invention, where FIG. 9(a) is a plan view, and FIG. 9(b), FIG. 9(c) and FIG. 9(d) are views in the cross sections Y1-Y1′, X1-X1′ and Y2-Y2′, respectively, in FIG. 9(a);

[FIG. 10] is a schematic diagram illustrating a method for forming a contact plug according to an exemplary embodiment of the present invention, where FIG. 10(a) is a plan view, and FIG. 10(b), FIG. 10(c) and FIG. 10(d) are views in the cross sections Y1-Y1′, X1-X1′ and Y2-Y2′, respectively, in FIG. 10(a);

[FIG. 11] is a schematic diagram illustrating a method for forming a contact plug according to an exemplary embodiment of the present invention, where FIG. 11(a) is a plan view, and FIG. 11(b), FIG. 11(c) and FIG. 11(d) are views in the cross sections Y1-Y1′, X1-X1′ and Y2-Y2′, respectively, in FIG. 11(a);

[FIG. 12] is a schematic diagram illustrating a method for manufacturing a semiconductor device according to a different exemplary embodiment of the present invention, where FIG. 12(a) is a plan view, and FIG. 12(b1), FIG. 12(c1) and FIG. 12(c2) are views in the cross sections Y1-Y1′, X1-X1′ and X2-X2′, respectively, in FIG. 12(a);

[FIG. 13] is a schematic diagram illustrating a method for manufacturing a semiconductor device according to the different exemplary embodiment of the present invention, where FIG. 13(a) is a plan view, and FIG. 13(b1), FIG. 13(c1) and FIG. 13(c2) are views in the cross sections Y1-Y1′, X1-X1′ and X2-X2′, respectively, in FIG. 13(a);

[FIG. 14] is a schematic diagram illustrating a method for manufacturing a semiconductor device according to the different exemplary embodiment of the present invention, where FIG. 14(a) is a plan view, and FIG. 14(b1), FIG. 14(c1) and FIG. 14(c2) are views in the cross sections Y1-Y1′, X1-X1′ and X2-X2′, respectively, in FIG. 14(a);

[FIG. 15] is a schematic diagram illustrating a method for manufacturing a semiconductor device according to the different exemplary embodiment of the present invention, where FIG. 15(a) is a plan view, and FIG. 15(b1), FIG. 15(c1) and FIG. 15(c2) are views in the cross sections Y1-Y1′, X1-X1′ and X2-X2′, respectively, in FIG. 15(a);

[FIG. 16] is a schematic diagram illustrating a method for manufacturing a semiconductor device according to the different exemplary embodiment of the present invention, where FIG. 16(a) is a plan view, and FIG. 16(b1), FIG. 16(c1) and FIG. 16(c2) are views in the cross sections Y1-Y1′, X1-X1′ and X2-X2′, respectively, in FIG. 16(a);

[FIG. 17] is a schematic diagram illustrating a method for manufacturing a semiconductor device according to the different exemplary embodiment of the present invention, where FIG. 17(a) is a plan view, and FIG. 17(b1), FIG. 17(b2), FIG. 17(c1) and FIG. 17(c2) are views in the cross sections Y1-Y1′, Y2-Y2′, X1-X1′ and X2-X2′, respectively, in FIG. 17(a);

[FIG. 18] is a schematic diagram illustrating a method for manufacturing a semiconductor device according to the different exemplary embodiment of the present invention, where FIG. 18(a) is a plan view, and FIG. 18(b1), FIG. 18(b2), FIG. 18(c1) and FIG. 18(c2) are views in the cross sections Y1-Y1′, Y2-Y2′, X1-X1′ and X2-X2′, respectively, in FIG. 18(a);

[FIG. 19] is a schematic diagram illustrating a method for manufacturing a semiconductor device according to the different exemplary embodiment of the present invention, where FIG. 19(a) is a plan view, and FIG. 19(b1), FIG. 19(b2), FIG. 19(c1) and FIG. 19(c2) are views in the cross sections Y1-Y1′, Y2-Y2′, X1-X1′ and X2-X2′, respectively, in FIG. 19(a);

[FIG. 20] is a schematic diagram illustrating a method for manufacturing a semiconductor device according to the different exemplary embodiment of the present invention, where FIG. 20(a) is a plan view, and FIG. 20(b1), FIG. 20(b2), FIG. 20(c1) and FIG. 20(c2) are views in the cross sections Y1-Y1′, Y2-Y2′, X1-X1′ and X2-X2′, respectively, in FIG. 20(a);

[FIG. 21] is a schematic diagram illustrating a method for manufacturing a semiconductor device according to the different exemplary embodiment of the present invention, where FIG. 21(a) is a plan view, and FIG. 21(b1), FIG. 21(b2), FIG. 21(c1) and FIG. 21(c2) are views in the cross sections Y1-Y1′, Y2-Y2′, X1-X1′ and X2-X2′, respectively, in FIG. 21(a);

[FIG. 22] is a schematic diagram illustrating a method for manufacturing a semiconductor device according to a variant example of the different exemplary embodiment of the present invention, where FIG. 22(a) is a plan view, and FIG. 22(b1), FIG. 22(b2) and FIG. 22(c) are views in the cross sections Y1-Y1′, Y2-Y2′ and X1-X1′, respectively, in FIG. 22(a);

[FIG. 23] is a schematic diagram illustrating a method for manufacturing a semiconductor device according to the variant example of the different exemplary embodiment of the present invention, where FIG. 23(a) is a plan view, and FIG. 23(b1), FIG. 23(b2) and FIG. 23(c) are views in the cross sections Y1-Y1′, Y2-Y2′ and X1-X1′, respectively, in FIG. 23(a);

[FIG. 24] is a schematic diagram illustrating a method for manufacturing a semiconductor device according to the variant example of the different exemplary embodiment of the present invention, where FIG. 24(a) is a plan view, and FIG. 24(b1), FIG. 24(b2) and FIG. 24(c) are views in the cross sections Y1-Y1′, Y2-Y2′ and X1-X1′, respectively, in FIG. 24(a);

[FIG. 25] is a schematic diagram illustrating a method for manufacturing a semiconductor device according to the variant example of the different exemplary embodiment of the present invention, where FIG. 25(a) is a plan view, and FIG. 25(b1), FIG. 25(b2) and FIG. 25(c) are views in the cross sections Y1-Y1′, Y2-Y2′ and X1-X1′, respectively, in FIG. 25(a);

[FIG. 26] is a schematic diagram illustrating a method for manufacturing a semiconductor device according to the variant example of the different exemplary embodiment of the present invention, where FIG. 26(a) is a plan view, and FIG. 26(b1), FIG. 26(b2) and FIG. 26(c) are views in the cross sections Y1-Y1′, Y2-Y2′ and X1-X1′, respectively, in FIG. 26(a);

[FIG. 27A] FIG. 27(a) is a schematic plan view of a semiconductor device 100 according to an exemplary embodiment of the present invention;

[FIG. 27B] FIG. 27(b1) is a view in the cross section Y1-Y1′ in FIG. 27(a);

[FIG. 27C] FIG. 27(b2) is a view in the cross section Y2-Y2′ in FIG. 27(a);

[FIG. 27D] FIG. 27(c) is a view in the cross section X1-X1′ in FIG. 27(a);

[FIG. 28] illustrates a step in the manufacture of the semiconductor device 100 shown in FIG. 27, where FIG. 28(a) is a schematic plan view, and FIG. 28(b) and FIG. 28(c) are views in the cross sections Y1-Y1′ and X1-X1′, respectively, in FIG. 28(a);

[FIG. 29] illustrates a step in the manufacture of the semiconductor device 100 shown in FIG. 27, where FIG. 29(a) is a schematic plan view, and FIG. 29(b) and FIG. 29(c) are views in the cross sections Y1-Y1′ and X1-X1′, respectively, in FIG. 29(a);

[FIG. 30] illustrates a step in the manufacture of the semiconductor device 100 shown in FIG. 27, where FIG. 30(a) is a schematic plan view, and FIG. 30(b) and FIG. 30(c) are views in the cross sections Y1-Y1′ and X1-X1′, respectively, in FIG. 30(a);

[FIG. 31] illustrates a step in the manufacture of the semiconductor device 100 shown in FIG. 27, where FIG. 31(a) is a schematic plan view, and FIG. 31(b) and FIG. 31(c) are views in the cross sections Y1-Y1′ and X1-X1′, respectively, in FIG. 31(a);

[FIG. 32] illustrates a step in the manufacture of the semiconductor device 100 shown in FIG. 27, where FIG. 32(a) is a schematic plan view, and FIG. 32(b), FIG. 32(c) and FIG. 32(d) are views in the cross sections Y1-Y1′, X1-X1′ and X2-X2′, respectively, in FIG. 32(a);

[FIG. 33] illustrates a step in the manufacture of the semiconductor device 100 shown in FIG. 27, where FIG. 33(a) is a schematic plan view, and FIG. 33(b), FIG. 33(c) and FIG. 33(d) are views in the cross sections Y1-Y1′, X1-X1′ and X2-X2′, respectively, in FIG. 33(a);

[FIG. 34] illustrates a step in the manufacture of the semiconductor device 100 shown in FIG. 27, where FIG. 34(a) is a schematic plan view, and FIG. 34(b), FIG. 34(c) and FIG. 34(d) are views in the cross sections Y1-Y1′, X1-X1′ and X2-X2′, respectively, in FIG. 34(a);

[FIG. 35] illustrates a step in the manufacture of the semiconductor device 100 shown in FIG. 27, where FIG. 35(a) is a schematic plan view, and FIG. 35(b), FIG. 35(c) and FIG. 35(d) are views in the cross sections Y1-Y1′, X1-X1′ and X2-X2′, respectively, in FIG. 35(a);

[FIG. 36] illustrates a step in the manufacture of the semiconductor device 100 shown in FIG. 27, where FIG. 36(a) is a schematic plan view, and FIG. 36(b) and FIG. 36(c) are views in the cross sections Y1-Y1′ and X1-X1′, respectively, in FIG. 36(a);

[FIG. 37A] illustrates a step in the manufacture of the semiconductor device 100 shown in FIG. 27, where FIG. 37(a) is a schematic plan view;

[FIG. 37B] FIG. 37(b) is a view in the cross section Y1-Y1′ in FIG. 37(a);

[FIG. 37C] FIG. 37(c) is a view in the cross section X1-X1′ in FIG. 37(a);

[FIG. 38A] illustrates a step in the manufacture of the semiconductor device 100 shown in FIG. 27, where FIG. 38(a) is a schematic plan view;

[FIG. 38B] FIG. 38(b1), FIG. 38(b2) and FIG. 38(c) are views in the cross sections Y1-Y1′, Y2-Y2′ and X1-X1′, respectively, in FIG. 38(a);

[FIG. 39] illustrates a step in the manufacture of the semiconductor device 100 shown in FIG. 27, where FIG. 39(b1), FIG. 39(b2) and FIG. 39(c) are views in cross section corresponding to the cross sections Y1-Y1′, Y2-Y2′ and X1-X1′, respectively, in FIG. 38(a);

[FIG. 40A] illustrates a step in the manufacture of the semiconductor device 100 shown in FIG. 27, where FIG. 40(a) is a schematic plan view;

[FIG. 40B] FIG. 40(b1), FIG. 40(b2) and FIG. 40(c) are views in the cross sections Y1-Y1′, Y2-Y2′ and X1-X1′, respectively, in FIG. 40(a);

[FIG. 41A] illustrates a step in the manufacture of the semiconductor device 100 shown in FIG. 27, where FIG. 41(a) is a schematic plan view; and

[FIG. 41B] FIG. 41(b1), FIG. 41(b2) and FIG. 41(c) are views in the cross sections Y1-Y1′, Y2-Y2′ and X1-X1′, respectively, in FIG. 41(a).

### MODE OF EMBODIMENT OF THE INVENTION

Preferred exemplary embodiments of the present invention will be described below with reference to the figures, but the present invention is not limited just to these exemplary embodiments; also included are suitable modifications that can be made, as required, by a person skilled in the art, within the scope of the present invention.

### Exemplary Embodiment 1

FIG. 1 and FIG. 7-11 are outline diagrams schematically showing a method for forming a contact plug according to a mode of embodiment of the present invention, where (a) is a plan view, (b) is a view in the cross section Y1-Y1′ in (a), (c) is a view in the cross section X1-X1′ in (a), and (d) is a view in the cross section Y2-Y2′ in (a). FIG. 1 is shared with the conventional example.

First of all, in the same way as in the conventional example, first line patterns 52 extending in a first direction (X-direction) and second line patterns 53 extending across the first line patterns 52 in a second direction (Y-direction) and having inclined side surfaces are formed on a substrate 51, and a large contact hole (referred to below as the first contact hole) 54 enclosed by the first and second line patterns is formed, as shown in FIG. 1. A plurality of the first line patterns 52 are formed at predetermined intervals in the Y-direction and a plurality of the second line patterns 53 are formed with a predetermined bottom surface gap in the X-direction and an upper surface gap which is wider than the bottom surface gap. The second line patterns 53 are not limited to a shape having inclined side surfaces such as that shown in FIG. 1, and line patterns having vertical side surfaces are equally feasible. Conversely, the first line patterns 52 are not limited to a shape having vertical side surfaces, and patterns having side surfaces which are inclined in the same way as the second line patterns 53 are equally feasible. The first line patterns 52 and the second line patterns 53 do not need to be made from one type of material, and they may be formed from a plurality of materials, but the surface thereof is preferably formed from an insulating material having different etching selectivity than a first insulating film which is formed in a subsequent step. For example, if the first insulating film is a silicon dioxide film, the surfaces of the first line patterns 52 and the second line patterns 53 are preferably covered by a silicon nitride film or the like. When the surfaces of the first line patterns 52 and the second line patterns 53 are covered all together by a silicon nitride film or the like, the surface of the substrate 51 is also covered, but this does not present any problems. Furthermore, in this example, the first line patterns 52 and the second line patterns 53 are formed by orthogonal patterns and the first contact hole 54 is formed as a rectangular pattern, but this is not limiting and cases in which the first line patterns 52 and the second line patterns 53 are not orthogonal are equally feasible. In that case, the first contact hole 54 has a parallelogram shape.

Next, as shown in FIG. 7, a first insulating film 61 is formed to a thickness that forms a recess 62 between the upper surfaces of the second line patterns 53. This is normally formed to a thickness constituting the width in the X-direction of the contact plug to be formed. At this point, the first insulating film 61 on the upper surface of the second line patterns 53 is denoted 61a, the first insulating film 61 on the side surfaces of the second line patterns 53 is denoted 61b, and the first insulating film 61 on the substrate 51, i.e. on the bottom part of the recess 62, is denoted 61c. If the gaps between the first line patterns 52 are greater than twice the thickness of the first insulating film 61, the recess 62 is also formed between the upper surfaces of the first line patterns 52 and the first insulating film 61c has substantially the same thickness as the first insulating film 61a and the first insulating film 61b. Here, the recess 62 has a first bottom part 62a at the upper surface of the first line patterns 52, and has a second bottom part 62b, which is at a lower level than the first bottom part, between the first line patterns 52. If the gaps between the first line patterns 52 are equal to or less than twice the thickness of the first insulating film 61, the bottom part of the recess 62 is substantially flat in the Y-direction at the upper surface of the first line patterns 52 and between the first line patterns 52, thereby forming the first bottom part 62a. The recess 62 is formed in a self-aligning manner in substantially the center between the second line patterns 53. According to the present invention, the second line patterns 53 are formed at a higher level than the first line patterns 52, so it is possible to form the recess 62 between the second line patterns 53 even if the spacing of the first line patterns is narrow and the areas between the first line patterns 52 are filled by the first insulating film 61. Furthermore, the side surfaces of the second line patterns 53 are inclined, which makes it easier to ensure a margin for forming the recess 62.

A first mask film 63 is then formed by filling the recess 62, as shown in FIG. 8. Any material may be used for the first mask film 63 provided that such material has different etching selectivity than the first insulating film 61. However, when there is a large gap between the first line patterns and the second bottom part 62b is formed in the recess 62, the first mask film 63 remains in contact with the contact plug which is ultimately formed, so the contact surface is an insulating material. The first mask film 63 may therefore be a single-layer film which is a second insulating film having different etching selectivity than the first insulating film 61, or a laminated film in which a semiconductive film or a conductive film such as polysilicon is laminated on the second insulating film. For example, if the first insulating film 61 is a silicon dioxide film, the second insulating film may be formed by a silicon nitride film or the like. Furthermore, the first mask film may also be an organic film such as a BARC (bottom anti-reflection coating) or the like.

Next, as shown in FIG. 9, the first mask film 63 and the first insulating film 61 are etched back by a dry etching method under conditions such that the etching rate of the first insulating film 61 is greater than that of the first mask film 63. By doing so, etching proceeds and at the point when the upper surface 61a of the first insulating film 61 is exposed, etching of the first insulating film 61 progresses more rapidly than that of the first mask film 63. As a result, when the etching has been completed, the underlying first insulating film 61 remains as an insulating film comprising only the first insulating film 61c at the lower part of the first mask film 63 inside the recess 62, and the first insulating film 61b at the lateral wall section does not remain. Second contact holes 64 are formed in this way. When the surfaces of the first line patterns 52 and the second line patterns 53 are covered all together in the step shown in FIG. 1 by a material having different etching selectivity than the first insulating film such as a silicon nitride film, a silicon nitride film remains on the bottom of the second contact holes 64, but this is further etched to expose the surface of the substrate 1. The second contact holes 64 are separated into individual bottom parts by the first line patterns 52 and second line patterns 53 and the residual first insulating film 61c, and is defined in the following manner: 64a, 64b, 64c in the X-direction, and 64c-1, 64c-2 and 64c-3 in the Y-direction.

Next, as shown in FIG. 10, a conductive material 55 is formed over the whole surface by filling the second contact holes 64. Finally, as shown in FIG. 11, the conductive material 55 embedded in each second contact hole 64 is separated in the Y-direction by the first line patterns and is separated in the X-direction by the second line patterns 53 and the first insulating film 61c by performing planarization in such a way that the upper surface of the first line patterns 52 is exposed, and the contact plugs 55a-1 to 55a-3, 55b-1 to 55-b3, 55c-1 to 55c-3 and 55d-1 to 55d-3 are completed. FIG. 11 shows an arrangement in which the first mask film 63 remains, but when the first insulating film 61c portion is thicker than the height of the first line patterns 52 because of the gap between the first line patterns 52, the first mask film 63 does not remain. When the first mask film 63 does not remain, it is possible to use a conductive material or a semiconductive material as the first mask film 63; for example, etch-back can be carried out at the same time as the contact plug is etched back provided that the first mask film 63 is formed from the same material as the conductive material forming the contact plug. Each contact plug may be reduced to a level below the upper surface of the first line patterns etc. by further etching back each contact plug.

According to this mode of embodiment, the first insulating film that constitutes an isolation insulating film is formed at an earlier stage inside the first contact hole 54, and as shown in FIG. 6(e), the residue 55r of the conductive material remains under the isolation insulating film 58 and there is no possibility of short-circuiting occurring between the two contact plugs (twin plugs) formed inside the first contact hole 54.

Furthermore, according to a mode of embodiment of the present invention, two second contact holes having a symmetrical structure can be formed in a self-aligning manner from a large first contact hole having a margin. The width of the second contact holes in the first direction can be adjusted using the thickness of the first insulating film, so it is possible to form second contact holes having a very small width below the limits of lithography, which makes this suitable for miniaturizing elements.

### Exemplary Embodiment 2

In Exemplary Embodiment 1 described above, the first contact hole was formed using line patterns having two different heights, but the first contact holes may equally be formed by two-stage etching which is used in a dual-Damascene process or the like, in addition to combinations of line patterns. In this exemplary embodiment a description will be given of a method for forming wiring with contact plugs by a dual-Damascene process.

FIG. 12 to FIG. 21 are process views in cross section illustrating the method for manufacturing a semiconductor device according to this exemplary embodiment, where each (a) drawing is a plan view, each (b1) drawing is a view in the cross section Y1-Y1′, each (b2) drawing is a view in the cross section Y2-Y2′, each (c1) drawing is a view in the cross section X1-X1′, and each (c2) drawing is a view in the cross section X2-X2′.

First of all, as shown in FIG. 12, a first recess 73 is formed by means of first-stage etching in an interlayer film 72 formed on a substrate 71, and a trench 74 including a first contact hole 73′ in which the surface of the substrate 71 is exposed is formed in the region of a first recess 73 by means of second-stage etching, as shown in FIG. 13. Here, the first contact hole 73′ has a rectangular shape, but this is not limiting and other shapes, e.g. an elliptical shape, may be adopted by varying the shape of the first-stage etching. The bottom of the first contact hole 73′ which is formed comprises a second bottom surface 73a where the surface of the substrate 71 is exposed, and the bottom surface of the trench 74 comprises a first bottom surface 74a formed in the interlayer film 72. Furthermore, the lateral walls of the trench 74 in the X-direction are denoted as first lateral walls 74b. The first lateral walls 74b are vertical in this example but they may equally have a tapered shape as described in Exemplary Embodiment 1. Furthermore, the trench 74 is wider in the X-direction than the first recess 73 produced by means of the first-stage etching, so the second bottom part 74a is also formed in the X-direction but the formation of this kind of step shape does not present any problem. However, if the first contact hole 73′ is completely concealed under the recess resulting from the first insulating film which is formed at a subsequent stage, the second bottom surface 73a is not readily exposed and if the width of the first contact hole 73′ which lies on the outside in the X-direction from below the recess is inadequate, it may not be possible to ensure sufficient contact surface area with the underlayer. The step shape is adjusted to take account of this.

Next, as shown in FIG. 14, a liner insulating film 75 is formed over the whole surface. In this example, if the interlayer film 72 is formed from a silicon dioxide film, for example, which does not have adequate etching selectivity with respect to the first insulating film (e.g., a silicon dioxide film) formed subsequently, the liner insulating film 75 is formed by an insulating film, e.g. a silicon nitride film, which has adequate etching selectivity with respect to the first insulating film. This step is unnecessary if the interlayer film 72 is made of a material having adequate etching selectivity with respect to the first insulating film. The first contact hole after formation of the liner insulating film is denoted 73″ and the trench is denoted 74′.

Next, as shown in FIG. 15, a first insulating film (a silicon dioxide film) 76 is formed in such a way that a recess 77 is formed between the first lateral walls 74b. Here, the first contact hole 73″ is filled because the width thereof in the Y-direction is less than twice the thickness of the first insulating film, and the recess 77 extending in the Y-direction is formed in the central region of the wiring trench 74′.

After this, a first mask film (second insulating film (silicon nitride film)) 78 is formed by filling the recess 77 in the same way as in Exemplary Embodiment 1 (FIG. 16), etch-back is carried out under conditions such that the etching rate of the underlying first insulating film 76 is greater than that of the first mask film 78 (FIG. 17), and the exposed liner insulating film 75 is etched back whereby divided wiring trenches 74L and 74R and second contact holes 73L and 73R exposing a second bottom surface 73a and a first bottom surface 74a are formed (FIG. 18).

After this, conductive material 79 is formed over the whole surface by filling the wiring trenches 74L and 74R and the second contact holes 73L and 73R (FIG. 19), and when etch-back is carried out by CMP or the like until the upper surface of the interlayer film 72 is exposed, it is possible to form two wires 79WL and 79WR, and two contact plugs 79CL and 79CR, as shown in FIG. 20. Furthermore, when etch-back is carried out until the second bottom part 74a is exposed, it is possible to form two contact plugs 79CL and 79CR, as shown in FIG. 21.

### Variant Example

The abovementioned exemplary embodiment describes a case in which the first contact hole is divided to form two second contact holes, and two contact plugs are formed, but the present invention is not limited by this and it is also possible to fill a large first contact hole on one side and to form one small second contact hole.

FIG. 22 to FIG. 26 are process views illustrating this variant example, where (a) is a plan view, (b1) is a view in the cross section Y1-Y1′, (b2) is a view in the cross section Y2-Y2′, and (c) is a view in the cross section X1-X1′. In this variant example, a procedure will be described in which two dual-Damascene wires are formed in accordance with the inventive method with respect to lower layer wiring 82A, 82B (also referred to below simply as lower layer wiring 82) which is embedded as a base in a first interlayer insulating film 81 and extends in the X-direction.

First of all, as shown in FIG. 22, two first contact holes 84A and 84B are formed above lower layer wiring 82 by means of first-stage etching in the same way as in Exemplary Embodiment 2, in a second interlayer insulating film 83 formed on the lower layer wiring 82, a trench 85 extending in the Y′-direction is formed by means of second-stage etching, and lower layer wiring 82A and lower layer wiring 82B are exposed at the bottom of the first contact holes 84A and 84B, respectively. The first contact holes 84A and 84B are formed against different side surfaces of the trench 85.

Next, as shown in FIG. 23, a liner insulating film 86 is formed in the same way as in Exemplary Embodiment 2. Then, as shown in FIG. 24, a first insulating film (silicon dioxide film) 87 is formed in such a way as to form a recess 88 in the center of the trench 85. The recess 88 is formed extending in the direction of extension (the Y′-direction) of the trench 85.

After this, a first mask film (second insulating film (silicon nitride film)) 89 is formed in the same way as in Exemplary Embodiment 1 by filling the recess 88, etch-back is performed under conditions such that the etching rate of the underlying first insulating film 87 is greater than that of the first mask film 89, and the exposed liner nitride film 86 is etched back to form divided wiring trenches 85L and 85R, and second contact holes 84A′ and 84B′ exposing the surface of the lower layer wiring 82 (FIG. 25).

After this, conductive material 90 is formed over the whole surface by filling the wiring trenches 85L and 85R and the second contact holes 84A′ and 84B′, and planarization is carried out in order to form upper layer wiring 90WR connected to the lower layer wiring 82A by a contact 90CR, and upper layer wiring 90WL connected to the lower layer wiring 82B by a contact 90CL, as shown in FIG. 26.

According to this variant example, it is thus possible to form miniature contacts together with miniature wiring, and it is also possible to freely set the position of the contact. It should be noted that the width of the trench 85 which is initially formed does not have to be fixed and the trench does not need to extend in a straight line either. The width of the wiring which is formed may be controlled by the thickness of the first insulating film 87 on the trench lateral walls, and the width of the recess 88 formed in the first insulating film 87 is also greater if the trench width is increased. Furthermore, according to this variant example, the first interlayer insulating film 81 and the second interlayer insulating film 83 are divided, but a single-layer interlayer insulating film in which the lower layer wiring 82 is embedded is equally feasible.

### Example of Application

An example in which the inventive method is applied to an actual semiconductor device will be described next. A semiconductor device 100 according to this example of application is a DRAM; FIG. 27(a) is a schematic plan view, FIG. 27(b1) is a view in the cross section Y1-Y1′ in FIG. 27(a), FIG. 27(b2) is a view in the cross section Y2-Y2′ in FIG. 27(a), and FIG. 27(c) is a view in the cross section X1-X1′ in FIG. 27(a). FIG. 28 to FIG. 41 are views in cross section of the series of steps in the manufacture of the semiconductor device 100 according to this example of application, and in each sub-drawing (a) is a schematic plan view, (b) or (b1) is a view in the cross section Y1-Y1′ in (a), (b2) is a view in the cross section Y2-Y2′ in (a), (c) is a view in the cross section X1-X1′ in (a), and (d) is a view in the cross section X2-X2′.

The semiconductor device 100 according to this example of application will be described first of all with reference to FIG. 27.

The semiconductor device 100 constitutes a DRAM memory cell. A plurality of element isolation regions 2 extending continuously in the X′-direction (third direction) and a plurality of active regions 1A likewise extending continuously in the X′-direction are disposed at equal intervals and an equal pitch alternately in the Y-direction (second direction) on a semiconductor substrate 1. The element isolation regions 2 are formed by an element isolation insulating film embedded in a trench. The following are disposed extending continuously in the Y-direction across the plurality of element isolation regions 2 and the plurality of active regions 1A: a first embedded word line (referred to below as a first word line) 10a, a second embedded word line (referred to below as a second word line) 10b, a third embedded word line (referred to below as a third word line) 10d, and a fourth embedded word line (referred to below as a fourth word line) 10e. Furthermore, a dummy word line 10c is disposed in such a way as to lie between the second word line 10b and the third word line 10d. The active regions 1A are element-isolated by means of a field shield afforded by the dummy word line 10c, and the active region 1A positioned to the left of the dummy word line 10c forms a first active region 1Aa, while the active region 1A positioned to the right forms a second active region 1Ab. First to third bit lines (BL) 16a-16c are provided extending in the X-direction (first direction).

The first active region 1Aa comprises: a second capacitance contact region 30b disposed adjacently to the left of the dummy word line 10c; the second word line 10b disposed adjacent to the second capacitance contact region 30b; a contact region 17c with a third BL 16c (third BL contact region) disposed adjacent to the second word line 10b; the first word line 10a disposed adjacent to the third BL contact region 17c; and a first capacitance contact region 30a disposed adjacent to the first word line 10a. The first capacitance contact region 30a, first word line 10a and third BL contact region 17c form a first cell transistor Tr1, and the third BL contact region 17c, second word line 10b and second capacitance contact region 30b form a second cell transistor Tr2.

The second active region 1Ab comprises: a third capacitance contact region 30c disposed adjacently to the right of the dummy word line 10c; the third word line 10d disposed adjacent to the third capacitance contact region 30c; a contact region 17b with a second BL 16b (second BL contact region) disposed adjacent to the third word line 10d; the fourth word line 10e disposed adjacent to the second BL contact region 17b; and a fourth capacitance contact region (not depicted) disposed adjacent to the fourth word line 10e. The third capacitance contact region 30c, third word line 10d and second BL contact region 17b form a third cell transistor Tr3, and the second BL contact region 17b, fourth word line 10e and fourth capacitance contact region which is not depicted form a fourth cell transistor Tr4.

The dummy word line 10c and the second capacitance contact region 30b and third capacitance contact region 30c disposed adjacently to the left and right of the dummy word line 10c form a dummy transistor DTr1 between the first active region 1Aa and the second active region 1Ab. The memory cell according to this example of application is constructed by arranging a plurality of first active regions 1Aa and second active regions 1Ab in the X-direction with the dummy word line 10c interposed.

Trenches for word lines also serving as gate electrodes of the transistor are provided in the semiconductor substrate 1. The first word line 10a, second word line 10b, dummy word line 10c, third word line 10d and fourth word line 10e are provided at the bottom of the respective trenches and are formed by a barrier film 7 and a metal film 8 such as tungsten with the interposition of a gate insulating film 6 covering the inner surface of each word line trench. Here, for the sake of convenience, the word lines passing through a first active region 1Aa′ are referred to as the first word line 10a and second word line 10b, and the word lines passing through a second active region 1Ab′ are referred to as the third word line 10d and fourth word line 10e, but each active region comprises two word lines and the dummy word line is disposed between the active regions. A cap insulating film 11 is provided by covering each word line and filling the respective trenches. A semiconductor pillar positioned to the left of the first word line 10a forms the first capacitance contact region 30a, and an impurity diffusion layer 29a forming either a source or drain is provided on the upper surface thereof. A semiconductor pillar positioned between the first word line 10a and the second word line 10b forms the third BL contact region 17c, and an impurity diffusion layer 12c forming the other of the source or drain is provided on the upper surface thereof. Furthermore, a semiconductor pillar positioned to the right of the second word line 10b forms the second capacitance contact region 30b, and an impurity diffusion layer 29b forming either a source or a drain is provided on the upper surface thereof. In addition, a semiconductor pillar positioned to the left of the third word line 10d forms the third capacitance contact region 30c, and an impurity diffusion layer 29c forming either a source or a drain is provided on the upper surface thereof. A semiconductor pillar positioned to the right of the third word line 10d then forms the second BL contact region 17b, and an impurity diffusion layer 12b forming the other of the source or drain is provided on the upper surface thereof

The second bit line (BL) 16b which is connected to the second impurity diffusion layer 17b in the second BL contact region 12b is provided on the cap insulating film 11 covering the upper surface of each word line, and the third bit line (BL) 16c which is connected to the third impurity diffusion layer 17c in the third BL contact region 12c is also provided thereon. In each bit line, a polysilicon layer 13 including a bit contact plug connected to an impurity diffusion layer, and a bit metal layer 14 formed thereon are provided, and a cover insulating film 15 is further provided on the upper surface thereof. Side walls 18 are provided on the lateral walls of each bit line, and a liner insulating film 19 is provided over the whole surface in such a way as to cover the bit lines. An embedded insulating film 20 filling the space of the recess formed between adjacent BL is provided on the liner insulating film 19. A capacitance contact 28 is provided passing through the embedded insulating film 20 and the liner film 19. The capacitance contact 28 connects first, second and third capacitance contact plugs 28a, 28b, 28c to the first, second and third capacitance contact regions 30a, 30b, 30c. The cap insulating film 11 on the dummy word line 10c comprises isolation insulating films (liner insulating film 19, side wall insulating film 24, first insulating film 25) which isolate the second and third capacitance contact plugs 28b, 28c. Respective contact pads 33 are connected to the upper parts of the first, second and third capacitance contact plugs 28a, 28b, 28c. A stopper film 34 is provided in such a way as to cover the capacitance contact pads 33. A lower electrode 35 is provided on the capacitance contact pads 33. A capacitor is formed by providing a capacitance insulating film 36 continuously covering the surfaces of the inner walls and outer walls of the lower electrode 35, and by providing an upper electrode 37 on the capacitance insulating film 36. The upper electrode 37 may comprise a stack of films, and a first upper electrode such as titanium nitride formed in a conformal manner on the capacitance insulating film 36, a filling layer (second upper electrode) such as doped polysilicon filling the space, and a plate electrode (third upper electrode) comprising a metal such as tungsten constituting a connection with upper layer wiring may also be included.

The method for manufacturing the semiconductor device 100 shown in FIG. 27 will be described below with the aid of FIG. 28 to FIG. 41.

First of all, as shown in FIG. 28, element isolation regions 2 filled by an insulating film comprising a silicon dioxide film extending in a first direction (X′-direction) are formed on a semiconductor substrate 1 by means of a known STI process. As a result, active regions 1A which are enclosed by the element isolation regions 2 and comprise the semiconductor substrate 1 are formed. It should be noted that here, the element isolation regions 2 are depicted as a laminated structure comprising a liner nitride film 2a and a silicon dioxide film 2b but this is not limiting.

A pad oxide film 3 comprising a silicon dioxide film is then formed over the whole surface of the semiconductor substrate 1 and an N-well region and a P-well region (not depicted) are formed by a known method through the pad oxide film 3.

Next, as shown in FIG. 29, a silicon dioxide film or the like is deposited on the semiconductor substrate 1, and a hard mask 4 which extends in the Y-direction and serves to form a plurality of trenches 5 at given intervals is patterned using a resist (not depicted).

The semiconductor substrate 1 is then etched by means of dry etching to form the trenches 5. Two pairs of adjacent trenches (5a and 5b; 5d and 5e) from among the plurality of trenches 5 are word line trenches in the same way as conventionally, and a trench 5c between two trenches (between 5b and 5d) corresponds to a conventional dummy word line trench, but according to the present invention, the trench 5c is formed into a diffusion layer isolation trench 29 in a subsequent step. At this point, the silicon dioxide film of the element isolation regions 2 is etched more deeply than the silicon of the semiconductor substrate 1, whereby saddle fins 1B are formed, as shown in FIG. 29(b). It is not essential to form the saddle fins 1B, and the trench depths in the active regions 1A and the element isolation regions 2 may be substantially equal. As a result, the active regions 1A are divided into a first portion lying between the pair of trenches 5a and 5b (or 5d and 5e), and a second portion lying between the pair of trenches 5a or 5b and 5c. The first portion forms a bit contact region to which bit lines are connected, and the second portion forms a capacitance contact region to which capacitance contact plugs are connected.

After this, a gate insulating film 6 is formed on the active regions 1A of the semiconductor substrate 1 using thermal oxidation and nitriding processes or the like. A liner nitride film in the element isolation regions 2 is also partially oxidized by means of thermal oxidation, and the silicon dioxide film is converted to a silicon oxynitride film by means of a subsequent nitriding process. As a result, the gate insulating film 6 is formed in succession on the insulating film of the element isolation regions 2 and also on the hard mask 4.

As shown in FIG. 30, a barrier film 7 such as titanium nitride and a metal film 8 such as tungsten are further deposited by means of CVD, for example, and then etched back, whereby word lines 10a, 10b, 10d, 10e are formed within the trenches 5a, 5b, 5d, 5e. At this point, the dummy word line 10c is formed in the same way inside the trench 5c.

Next, as shown in FIG. 31, a liner film is formed by means of CVD, for example, using a silicon nitride film or the like, in such a way as to cover the remaining metal film 8 and the inner walls of the trenches 5a-5e, although this is not depicted. A silicon dioxide film is deposited on the liner film. After this, CMP is carried out in order to planarize the surface until the liner film is exposed. In addition, the exposed liner film is removed and the hard mask 4 and silicon dioxide film are etched back to a predetermined height. As a result, embedded word lines filled with a cap insulating film 11 are formed. The cap insulating film 11 may be formed in such a way as to cover the hard mask 4 when the remaining hard mask 4 is thin, and said film maintains sufficient distance between the bit lines formed in a subsequent step and a diffusion layer which connects the capacitance contact plugs.

Next, as shown in FIG. 32, part of the hard mask 4 is removed using a photolithography technique and a dry etching technique, and bit line contact regions are formed; FIG. 32(d) shows a bit contact BC connected to the upper surface of the third BL contact region 17c. The bit contact is formed as a pattern with line-shaped openings extending in the same direction (the Y-direction) as the word lines 10. The surface (first portion) of the semiconductor substrate 1 is exposed at the region of intersection of the active regions with the pattern of the bit contact BC. After the bit contact BC has been formed, N-type impurity (arsenic or the like) is ion-implanted and an N-type impurity diffusion layer 12 is formed in the vicinity of the silicon surface. The N-type impurity diffusion layer 12 which has been formed functions as a transistor source/drain region. After this, a laminated film comprising a polysilicon film 13, a tungsten film 14 and a silicon nitride film 15 etc. is formed by means of CVD, for example. A line-shaped pattern is then formed extending in the direction intersecting the word lines 10 (the X-direction) using a photolithography technique and a dry etching technique, and bit lines 16 are formed. The polysilicon film 13 and the N-type impurity diffusion layer 12 under the bit lines are connected at the region of the silicon surface exposed inside the bit contact. In the portion shown in FIG. 32(d), the third BL 16c and the N-type impurity diffusion layer 12c are connected.

Next, as shown in FIG. 33, a silicon nitride film 18 covering the side surfaces of the bit lines 16 is formed, after which etching is used to remove part of the silicon dioxide film hard mask 4, the pad oxide film 3 and the cap insulating film 11, and the surface of the cap insulating film 11 is etched back in such a way to have substantially the same height as the silicon surface of the semiconductor substrate 1.

Next, as shown in FIG. 34, a liner film 19 covering the whole surface is formed by a silicon nitride film or the like using CVD, for example. A SOD film 20 which is a coating film is deposited in such a way as to fill the spaces between the bit lines, after which annealing is carried out in a high-temperature steam (H₂O) atmosphere in order to modify the film to a solid film. Planarization is carried out by means of CMP until the upper surface of the liner film 19 is exposed, after which a silicon dioxide film formed by CVD, for example, is formed as a cap silicon dioxide film 21 and the surface of the SOD film 20 is covered. A mask polysilicon film 22 is further formed on the cap silicon dioxide film 21.

Next, as shown in FIG. 35, a capacitance contact hole 23 is formed using a photolithography technique and a dry etching technique. Specifically, a line-shaped pattern is produced using a lithography technique and the bit lines 16 covered by the liner film 19 are formed into the first line patterns 52 shown in FIG. 1, while the SOD film 20, cap silicon dioxide film 21 and mask polysilicon film 22 are formed into the second line patterns 53 shown in FIG. 1. The second line patterns are formed as a pattern with line-shaped openings which extends in the Y-direction over the word lines 10a, 10b and 10d, 10e and opens over the dummy word line 10c. Furthermore, the side surfaces thereof are inclined and the upper part of the contact hole 23 is wider than the bottom part thereof in the X-direction. Conventionally, the liner film 19 is removed at this stage to expose the substrate surface and side walls are formed on the side surfaces of the bit lines, but the liner film 19 is not removed in this example of application.

Next, as shown in FIG. 36, a side wall film 24 is formed over the whole surface by a silicon nitride film using CVD, for example. Conventionally, the side wall film 24 is etched back to form the side walls on the side surfaces of the second line patterns and third side walls on the side surfaces of the bit lines and the semiconductor substrate surface is exposed, but the surface of the semiconductor substrate 1 is covered by the liner film 19 and the side wall film 24 in this example of application.

Next, as shown in FIG. 37, a first insulating film 25 and a first mask film (second insulating film) 26 are formed in succession. For the first insulating film 25, a silicon dioxide film is formed to a thickness of 20 nm using CVD, for example. At this point, recesses are formed between the second line patterns and the areas between the bit lines 16 are filled by the first insulating film 25. For the second insulating film 26, a silicon nitride film is formed to a thickness of 50 nm using CVD, for example. As a result, the recesses formed in the first insulating film 25 are filled. Here, the first insulating film on the second line patterns is denoted 25a, the first insulating film on the side surfaces of the second line patterns is denoted 25b, and the first insulating film on the bottom part of the contact hole 23 is denoted 25c; the second insulating film on the first insulating film 25a is denoted 26a, and the second insulating film inside the recesses formed in the first insulating film 25 is denoted 26b.

Next, as shown in FIG. 38, the second insulating film 26 is etched back by means of dry etching and the exposed first insulating film 25 is further etched back. Here, at the stage where the first insulating film 25 and the second insulating film 26 are both exposed, i.e. the stage where the second insulating film 26a has been removed, the etching is performed by selecting conditions such that the etching rate of the first insulating film 25 is greater. It is possible to select etching conditions suitable for the second insulating film 26 until the first insulating film 25 is exposed, but by performing etching under the abovementioned conditions such that the etching rate of the first insulating film 25 is greater, there is no need to switch the etching conditions and etching may be carried out continuously. As a result, the first insulating film 25a, 25b is etched to form a second contact hole (capacitance contact) 27. The first insulating film 25c lying under the second insulating film 26b remains without being etched and forms a capacitance contact isolation insulating film. The side wall insulating film 24 and the liner film 19 at the bottom of the capacitance contact 27 are etched as they are, thereby exposing the surface of the semiconductor substrate 1. Here, the side wall insulating film 24 and the liner film 19 on the upper surfaces of the bit lines exposed in the capacitance contact 27 are also etched to form side wall shapes. It should be noted that at the stage where the side wall insulating film 24 and the liner film 19 are etched, conditions may be selected such that the etching rate of the side wall insulating film 24 and the liner film 19, which are silicon nitride films, is greater than that of the first insulating film (a silicon dioxide film) 25. By doing so, it is possible to restrict etching of the cap insulating film 11 which is a silicon dioxide film exposed at the bottom of the capacitance contact 27, and it is also possible to suppress unnecessary side etching of the first insulating film 25. The capacitance contact 27 is separated in the X-direction by means of the second line patterns, the first insulating film 25, and a laminated film comprising the side wall insulating film 24 and the liner film 19, and the first contact hole 23 is divided in two. The capacitance contact 27 is continuous in the Y-direction on the bit lines, but it is also separated in the Y-direction by means of the bit lines 16 at the bottom part thereof.

Next, as shown in FIG. 39, the inside of the capacitance contact 27 is filled with polysilicon 28 doped with N-type impurity (phosphorus or the like) using CVD, for example. N-type impurity diffusion layers 29a, 29b, 29c are formed by means of the N-type impurity doped in the polysilicon 28 in the vicinity of the surface of the capacitance contact regions 30a, 30b, 30c constituting the second portion of the active regions 1A. The N-type impurity diffusion layers 29a, 29b, 29c which are formed function as a transistor source/drain region.

Next, as shown in FIG. 40, the polysilicon 28, second insulating film 26b and second line patterns are planarized by means of CMP. Here, planarization is carried out until the cover insulating film 15 on the bit lines is exposed, using said cover insulating film 15 as an etching stopper. As a result, a first capacitance contact plug 28a connected to the first capacitance contact region 30a, a second capacitance contact plug 28b connected to the second capacitance contact region 30b, and a third capacitance contact plug 28c connected to the third capacitance contact region 30c can be isolated in the Y-direction. The polysilicon is further etched back and the first to third capacitance contact plugs 28a-28c are completed. It should be noted that the planarization by means of CMP may be terminated at the point in time when the side wall insulating film 24 and liner film 19 on the bit lines 16 below the first insulating film 25c are exposed. In this case, the polysilicon 28 is formed on the cover insulating film 15 on the bit lines in the capacitance contact 27, so there is no isolation in the Y-direction, but isolation may be provided in the Y-direction by subsequent etch-back.

Next, as shown in FIG. 41, a barrier film 31 such as titanium nitride and a wiring material layer such as a metal film 32 which is tungsten or the like are embedded in the region inside the capacitance contact 27 in which the capacitance contact plugs 28a-28c are not embedded. A capacitance contact pad 33 is then formed using a photolithography technique and a dry etching technique. A silicide film such as cobalt silicide may be formed on the upper surfaces of the capacitance contact plugs 28a-28c in order to reduce the contact resistance with the capacitance contact pad 33.

After this, as shown in FIG. 27, a stopper film 34 is formed using a silicon nitride film in such a way as to cover the capacitance contact pad 33. A lower electrode 35 of a capacitor element is formed by titanium nitride or the like on the capacitance contact pad 33. A capacitance insulating film 36 is then formed in such a way as to cover the surface of the lower electrode 35, after which an upper electrode 37 of a capacitor element is formed by titanium nitride or the like. After this, multilayer wiring is formed by repeating a wiring formation step, although this is not depicted, and the semiconductor device 100 is formed.

It should be noted that in this example of application, it is not necessary to make the capacitance contact plugs 28a-28c lower than the cover insulating film 15 on the upper surfaces of the bit lines by means of etch-back, and then to form the contact pad 33. According to the present invention, the contact plugs formed inside one contact hole 23, i.e. the two capacitance contact plugs (28b and 28c in the figures) which are facing in the X-direction with the first insulating film 25c therebetween, employ the inclined surfaces of the second line patterns and may be formed in such a way that the distance between centers on the upper surfaces is greater than the distance between centers on the lower surfaces, so even if the lower electrode of the capacitor is formed directly on the capacitance contact plug, adequate spacing can be maintained between capacitors.

### KEY TO SYMBOLS

1 . . . Semiconductor substrate
1A . . . Active region
1Aa . . . First active region
1Ab . . . Second active region
1B . . . Saddle fin
2 . . . Element isolation region
2a . . . Liner nitride film
2b . . . Silicon dioxide film
3 . . . Pad oxide film
4 . . . Hard mask
5 . . . Word line trench
6 . . . Gate insulating film
7 . . . Barrier film
8 . . . Metal film
10a, 10b, 10d, 10e . . . Word line
10c . . . Dummy word line
11 . . . Cap insulating film
12 . . . N-type impurity diffusion layer
13 . . . Polysilicon film
14 . . . Tungsten film
15 . . . Silicon nitride film
16 . . . Bit line
17 . . . Bit line contact region
18 . . . Silicon nitride film
19 . . . Liner film
20 . . . SOD film
21 . . . Cap silicon dioxide film
22 . . . Mask polysilicon film
23 . . . First contact
24 . . . Side wall insulating film
25 . . . First insulating film
26 . . . First mask film (second insulating film)
27 . . . Capacitance contact (second contact hole)
28 . . . Polysilicon
28a-28c . . . Capacitance contact plug
29a-29c . . . N-type impurity diffusion layer
30a-30c . . . Capacitance contact region
31 . . . Barrier film
32 . . . Metal film
33 . . . Capacitance contact pad
34 . . . Stopper film
35 . . . Lower electrode
36 . . . Capacitance insulating film
37 . . . Upper electrode
51 . . . Substrate
52 . . . First line pattern
53 . . . Second line pattern
54 . . . First contact hole
55 . . . Conductive material
55a-1 to 55a-3, 55b-1 to 55b-3, 55c-1 to 55c-3, 55d-1 to 55d-3 . . . Contact plug
61 . . . First insulating film
62 . . . Recess
63 . . . First mask film
64 . . . Second contact hole
71 . . . Substrate
72 . . . Interlayer film
73 . . . First recess
73′, 73″ . . . First contact hole
73a . . . Second bottom surface
73L, 73R . . . Second contact hole
74, 74′ . . . Trench
74a . . . First bottom surface
74b . . . First lateral wall
74L, 74R . . . Wiring trench
75 . . . Liner insulating film
76 . . . First insulating film
77 . . . Recess
78 . . . First mask film (second insulating film)
79 . . . Conductive material
79WL, 79WR . . . Wiring
79CL, 79CR . . . Contact plug
81 . . . First interlayer insulating film
82 . . . Lower layer wiring
83 . . . Second interlayer insulating film
84A, 84B . . . First contact
84A′, 84B′ . . . Second contact hole
85 . . . Trench
85L, 85R . . . Wiring trench
86 . . . Liner insulating film
87 . . . First insulating film
88 . . . Recess
89 . . . First mask film (second insulating film)
90 . . . Conductive material
90WL, 90WR . . . Wiring
90CL, 90CR . . . Contact plug
100 . . . Semiconductor device

1. A method for manufacturing a semiconductor device, comprising:
forming a plurality of first line patterns extending in a first direction and arranged at predetermined intervals on a substrate;
forming a plurality of second line patterns which are at a higher level than the first line patterns and extend over the first line patterns in a second direction orthogonal to the first direction on the substrate;
forming a first insulating film having different etching selectivity than the surfaces of the first and second line patterns to a thickness that forms a recess between the second line patterns;
forming a first mask film which fills the recess and has different etching selectivity than the first insulating film on the first insulating film;
etching the first mask film to expose the first insulating film, the first insulating film is preferentially further etched so that the first insulating film below the first mask film in the recess remains, and an opening is formed which exposes part of the substrate surface enclosed by the first and second line patterns along the side surfaces of the second line patterns;
forming a conductive material by filling the opening; and
etching the conductive material back to expose the upper surface of the first line patterns, and forming a plurality of contact plugs which are separated in the second direction by the first line patterns and are separated in the first direction by the second line patterns and the first insulating film.

2. The method for manufacturing a semiconductor device as claimed in claim 1, wherein the second line patterns have an inclined side surface shape forming, in the first direction, a predetermined bottom surface gap and an upper surface gap which is wider than the bottom surface gap.

3. The method for manufacturing a semiconductor device as claimed in claim 1, wherein the forming the plurality of contact plugs is implemented by etching back the whole surface until the upper surface of the first line patterns is exposed.

4. The method for manufacturing a semiconductor device as claimed in claim 1, wherein forming the plurality of contact plugs is implemented by etching back the whole surface to a predetermined height level, then etching back the conductive material until the first line patterns are exposed and a level at or below the upper surface of the first line patterns is reached.

5. The method for manufacturing a semiconductor device as claimed in claim 1, comprising, after the second line patterns have been formed and before the first insulating film is formed, covering the substrate surface and the surfaces of the first and second line patterns by an insulating material having different etching selectivity than the first insulating film.

6. The method for manufacturing a semiconductor device as claimed in claim 1, wherein the first line patterns are disposed at intervals which are no greater than twice the thickness of the first insulating film, the first insulating film is formed filling the areas between the first line patterns, and the recess has a substantially flat bottom surface.

7. The method for manufacturing a semiconductor device as claimed in claim 1, wherein the first line patterns are disposed at intervals which are more than twice as wide as the thickness of the first insulating film, and the recess has a second bottom surface over the first line patterns and a first bottom surface at a lower level than the second bottom surface between the first line patterns.

8. The method for manufacturing a semiconductor device as claimed in claim 7, wherein the first mask film includes a shape formed by the second bottom surface and the first bottom surface, a second insulating film having different etching selectivity than the first insulating film.

9. The method for manufacturing a semiconductor device as claimed in claim 1, wherein the first insulating film is a silicon dioxide film and the first mask film is a silicon nitride film.

10. The method for manufacturing a semiconductor device as claimed in claim 1, comprising:
forming a plurality of element isolation regions extending in a third direction different than the first and second directions on the semiconductor substrate, and defining an active region extending in the third direction between the element isolation regions;
forming two pairs of adjacent embedded word lines extending in the second direction and forming an embedded dummy word line between the pairs of embedded word lines;
forming bit lines which are connected to the active region between the pairs of embedded word lines and are covered by an insulating film on the upper part and side surfaces on the semiconductor substrate as first line patterns; and
forming the second line patterns, the second line patterns extending in the second direction on the pairs of embedded word lines and opening over the active region on the embedded dummy word line and on both sides thereof,
wherein the contact plugs are connected to the active region on both sides of the embedded dummy word line.

11. The method for manufacturing a semiconductor device as claimed in claim 10, comprising:
after an insulating film has been formed on the lateral walls of the bit lines, performing etch-back until the semiconductor substrate surface in the region where the bit lines are not formed is exposed;
covering the whole surface with a liner insulating film having different etching selectivity than the first insulating film;
forming an embedded insulating film on the liner insulating film and filling the gaps between the bit lines;
forming a mask film on the bit lines and on the embedded insulating film, and forming the second line patterns including the embedded insulating film; and
forming a side wall insulating film having different etching selectivity than the first insulating film over the whole surface including the second line patterns, wherein the side wall insulating film and liner insulating film which are exposed at the bottom of an opening formed by preferentially removing the first insulating film are removed in order to expose the active region on both sides of the dummy word line.

12. The method for manufacturing a semiconductor device as claimed in claim 11, wherein the first insulating film is a silicon dioxide film and the liner insulating film and side wall insulating film are silicon nitride films.

13. The method for manufacturing a semiconductor device as claimed in claim 10, comprising forming a capacitor on the contact plug.

14. The method for manufacturing a semiconductor device as claimed in claim 13, wherein the capacitor comprises a cylindrical lower electrode which is electrically connected to the contact plug and has a bottom surface and side surfaces, and an upper electrode which faces an inner wall and an outer wall of the lower electrode with a capacitance insulating film interposed.

15. The method for manufacturing a semiconductor device as claimed in claim 13, comprising forming a pad electrode which electrically connects the contact plug and the lower electrode of the capacitor.

16. A method for manufacturing a semiconductor device, comprising:
forming a trench having a first bottom surface in an interlayer film, and forming a first contact hole having a second bottom surface at a lower level than the first bottom surface inside the trench;
forming a first insulating film to a thickness that forms a recess in the center between both lateral walls of the trench;
forming a first mask film filling the recess;
removing the first insulating film other than the first insulating film below the first mask film inside the recess to expose the first bottom surface and part of the second bottom surface; and
embedding a conductive material in contact with the first bottom surface and the second bottom surface.

17. The method for manufacturing a semiconductor device as claimed in claim 16, wherein the first contact hole is formed into a shape in which a recess formed in the first insulating film is positioned in the center of the first contact hole in the trench width direction, the shape projecting further toward both lateral walls of the trench than the side surfaces of the recess in the trench width direction, and two second contact holes are formed by means of the remaining first insulating film by splitting the first contact hole.

18. The method for manufacturing a semiconductor device as claimed in claim 16, wherein the first contact hole is formed into a shape that is provided further towards one lateral wall in the trench width direction, a recess formed by means of the first insulating film is positioned on one side end of the first contact hole, the shape projecting further toward one lateral wall of the trench than the side surface of the recess on one side surface of the trench, and two contact holes which are smaller than the first contact hole are formed by means of the remaining first insulating film.

19. The method for manufacturing a semiconductor device as claimed in claim 16, wherein the conductive material is embedded, after which the conductive material on the first bottom surface is removed.

20. The method for manufacturing a semiconductor device as claimed in claim 16, wherein the second bottom surface includes at least a conductive site having an underlayer structure at the region of contact with the conductive material.

21. The method for manufacturing a semiconductor device as claimed in claim 16, wherein the interlayer insulating film and the first insulating film comprise an insulating material containing silicon dioxide, and the method comprises, before the first insulating film is formed, forming a second insulating film having different etching selectivity than the first insulating film in the trench including the first and second bottom surfaces and on the inner wall of the first contact hole.

22. The method for manufacturing a semiconductor device as claimed in claim 21, wherein the first mask film and the second insulating film comprise silicon nitride.
